(19) United States
(12) Patent Application Publication
(10) Pub. No.: US 2014/0055599 A1
(43) Pub. Date: Feb. 27, 2014

(54) INSPECTION DEVICE, BONDING SYSTEM AND INSPECTION METHOD

(71) Applicant: TOKYO ELECTRON LIMITED, Tokyo (JP)

(72) Inventors: Shinji KOGA, Koshi City (JP); Akinori MIYAHARA, Koshi City (JP); Hiroshi TOMITA, Koshi City (JP); Shuji IWANAGA, Koshi City (JP); Takeshi TAMURA, Koshi City (JP)

(73) Assignee: TOKYO ELECTRON LIMITED, Tokyo (JP)

(21) Appl. No.: 13/967,938

(22) Filed: Aug. 15, 2013

(30) Foreign Application Priority Data
Aug. 23, 2012 (JP) 2012-184084

(51) Int. Cl. G01N 21/95; H04N 5/33

(52) U.S. Cl. CPC G01N 21/9501; H04N 5/33
USPC 348/87

(57) ABSTRACT

An inspection device for inspecting the interior of an overlapped substrate produced by bonding one substrate and another substrate, comprising: a first holding unit configured to hold the rear surface of the overlapped substrate and include a cutout formed to expose a portion of the rear surface of the overlapped substrate when viewed from the top; a second holding unit configured to hold and rotate the overlapped substrate; an infrared irradiator configured to irradiate the rear surface or front surface exposed from the cutout of the overlapped substrate held on the first holding unit with an infrared ray; and an image pickup unit configured to receive the infrared ray emitted from the infrared irradiator and image the overlapped substrate held on the first holding unit in division for each of regions exposed from the cutout.

### CROSS-REFERENCE TO RELATED APPLICATION

This application claims the benefit of Japanese Patent Application No. 2012-184084, filed on Aug. 23, 2012, in the Japan Patent Office, the disclosure of which is incorporated herein in its entirety by reference.

### TECHNICAL FIELD

The present disclosure relates to an inspection device for inspecting the interior of an overlapped substrate including substrates bonded together, a bonding system including the inspection device, and an inspection method using the inspection device.

### BACKGROUND

In recent years, semiconductor devices have been under high integration. When many highly-integrated semiconductor devices are arranged in a horizontal plane and are connected by wirings for final fabrication, there are problems of increase in wiring length, wiring resistance and wiring delay.

As one of attempts to avoid such problems, there has been proposed a three-dimensional (3D) integration technique for stacking semiconductor devices in three dimensions. This 3D integration technique uses, for example, a bonding system to bond two semiconductor wafers (hereinafter abbreviated as “wafers”) together. For example, the bonding system includes a surface hydrophilizing device for hydrophilizing the bonded surfaces of the substrate and a bonding device for bonding the substrates whose surfaces are hydrophilized by the surface hydrophilizing device. In this bonding system, after the surface hydrophilizing device hydrophilizes the substrate surfaces by supplying pure water onto the substrate surfaces, the bonding device bonds the substrates using a Van der Waals force and hydrogen bonding (inter-molecular force).

However, there may occur voids in a wafer produced by the bonding of the wafers (hereinafter referred to as an “overlapped wafer”). There are a variety of methods of inspecting these voids. For example, voids in the overlapped wafer are inspected by illuminating infrared ray on the overlapped wafer and imaging the infrared ray penetrating the overlapped wafer with a camera.

However, such conventional inspection methods cannot provide the ability to allow the infrared ray to transmit through a holding unit holding the overlapped wafer. This prevents the portion of the overlapped wafer held on the holding unit from being imaged, which may result in failure in proper inspection for the voids in the overlapped wafer.

### SUMMARY

Some embodiments of the present disclosure provide an inspection device for properly inspecting the interior of an overlapped substrate including substrates bonded together, a bonding system including the inspection device, and an inspection method using the inspection device

According to one embodiment of the present disclosure, there is provided an inspection device for inspecting the interior of an overlapped substrate produced by bonding one substrate and another substrate, which includes: a first holding unit configured to hold the rear surface of the overlapped substrate and include a cutout formed to expose a portion of the rear surface of the overlapped substrate when viewed from the top; a second holding unit configured to hold and rotate the overlapped substrate; an infrared irradiator configured to irradiate the rear surface or front surface exposed from the cutout of the overlapped substrate held on the first holding unit with an infrared ray; and an image pickup unit configured to receive the infrared ray emitted from the infrared irradiator and image the overlapped substrate held on the first holding unit in division for each of regions exposed from the cutout.

According to another embodiment of the present disclosure, there is provided a bonding system including an inspection device for inspecting the interior of an overlapped substrate produced by bonding one substrate and another substrate, which includes: a first holding unit configured to hold the rear surface of the overlapped substrate and include a cutout formed to expose a portion of the rear surface of the overlapped substrate when viewed from the top; a second holding unit configured to hold and rotate the overlapped substrate; an infrared irradiator configured to irradiate the rear surface or front surface exposed from the cutout of the overlapped substrate held on the first holding unit with an infrared ray; and an image pickup unit configured to receive the infrared ray emitted from the infrared irradiator and image the overlapped substrate held on the first holding unit in division for each of regions exposed from the cutout, comprising: a processing station including a plurality of processing apparatuses configured to perform a predetermined process to bond one substrate and another substrate, and a substrate transfer region for transferring the substrates before the bonding or an overlapped substrate after the bonding to the plurality of processing apparatuses; and a carry-in/carry-out station configured to carry the substrates before the bonding or the overlapped substrate after the bonding in/out of the processing station, wherein the inspection device is adjacent to the substrate transfer region in the processing station and is arranged in a side of the carry-in/carry-out station.

According to another embodiment of the present disclosure, there is provided an inspection method for inspecting the interior of an overlapped substrate produced by bonding one substrate and another substrate using an inspection device including: a first holding unit configured to hold the rear surface of the overlapped substrate and include a cutout formed to expose a portion of the rear surface of the overlapped substrate when viewed from the top; a second holding unit configured to hold and rotate the overlapped substrate; an infrared irradiator configured to irradiate the rear surface or front surface exposed from the cutout of the overlapped substrate held on the first holding unit with an infrared ray; and an image pickup unit configured to receive the infrared ray emitted from the infrared irradiator and image the overlapped substrate held on the first holding unit in division for each of regions exposed from the cutout, the method comprising: irradiating the rear surface or front surface of the overlapped substrate exposed from the cutout with the infrared ray from the infrared irradiator, under the condition where the overlapped substrate is held on the first holding unit, receiving the irradiated infrared ray in the image pickup unit, and imaging the overlapped substrate exposed from the cutout; rotating the overlapped substrate by means of the second holding unit, under the condition where the overlapped substrate is held on the second holding unit, such that a portion of the rear surface of the overlapped substrate, which is not imaged by the imaging, is exposed from the cutout; and repeatedly performing the imaging and the rotating in this order, imaging the whole overlapped substrate, and inspecting the interior of the overlapped substrate.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view showing a general configuration of a bonding system according to an embodiment.

FIG. 2 is a side view showing a general internal configuration of the bonding system according to the embodiment.

FIG. 3 is a side view showing a general configuration of an upper wafer and a lower wafer.

FIG. 4 is a longitudinal sectional view showing a general configuration of a surface modifying device.

FIG. 5 is a plan view of an ion passing structure.

FIG. 6 is a longitudinal sectional view showing a general configuration of a surface hydrophilizing device.

FIG. 7 is a cross sectional view showing a general configuration of a surface hydrophilizing device.

FIG. 8 is a cross sectional view showing a general configuration of a bonding device.

FIG. 9 is a longitudinal sectional view showing a general configuration of a bonding device.

FIG. 10 is a side view showing a general configuration of a positioning mechanism.

FIG. 11 is a plan view showing a general configuration of an inverting mechanism.

FIG. 12 is a side view showing a general configuration of the inverting mechanism.

FIG. 13 is another side view showing a general configuration of the inverting mechanism.

FIG. 14 is a side view showing a general configuration of a holding arm and a holding member.

FIG. 15 is a longitudinal sectional view showing a general configuration of an upper chuck and a lower chuck.

FIG. 16 is a plan view of the upper chuck when viewed from the bottom.

FIG. 17 is a plan view of the lower chuck when viewed from the top.

FIG. 18 is a cross sectional view showing a general configuration of an inspection device.

FIG. 19 is a longitudinal sectional view showing a general configuration of an inspection device.

FIG. 20 is a plan view showing a general configuration of a first holding unit.

FIG. 21 is a view used to explain an infrared ray traveling path between an infrared irradiator and an imaging pickup unit.

FIG. 22 is a perspective view showing a general configuration of a first direction changer and a second direction changer.

FIG. 23 is a flow chart showing main operations of a wafer bonding process.

FIG. 24 is a view used to explain adjustment of horizontal positions of an upper wafer and a lower wafer.

FIG. 25 is a view used to explain adjustment of vertical positions of an upper wafer and a lower wafer.

FIG. 26 is a view used to explain pressing of the central portion of the upper wafer and the central portion of the lower wafer in contact.

FIG. 27 is a view used to explain sequential contact of the upper wafer with the lower wafer.

FIG. 28 is a view used to explain contact of the surface of the upper wafer and the surface of the lower wafer.

FIG. 29 is a view used to explain bonding of the upper wafer and the lower wafer.

FIG. 30 is a view used to explain passing of an overlapped wafer from a wafer transfer device to elevation pins.

FIG. 31 is a view used to explain movement of a first holding unit from an exchange position to a rotation position.

FIG. 32 is a view used to explain passing of an overlapped wafer from a first holding unit to a second holding unit.

FIG. 33 is a view used to explain imaging of an overlapped wafer when the first holding unit is moved.

FIG. 34 is a view used to explain an overlapped wafer imaged in division.

FIG. 35 is a view used to explain an infrared ray traveling path between an infrared irradiator and an imaging pickup unit according to another embodiment.

FIG. 36 is a longitudinal sectional view showing a general configuration of an inspection device according to another embodiment.

FIG. 37 is a view used to explain an infrared ray traveling path between an infrared irradiator and an imaging pickup unit according to another embodiment.

FIG. 38 is a view used to explain an infrared ray traveling path between an infrared irradiator and an imaging pickup unit according to another embodiment.

FIG. 39 is a view used to explain an infrared ray traveling path between an infrared irradiator and an imaging pickup unit according to another embodiment.

### DETAILED DESCRIPTION

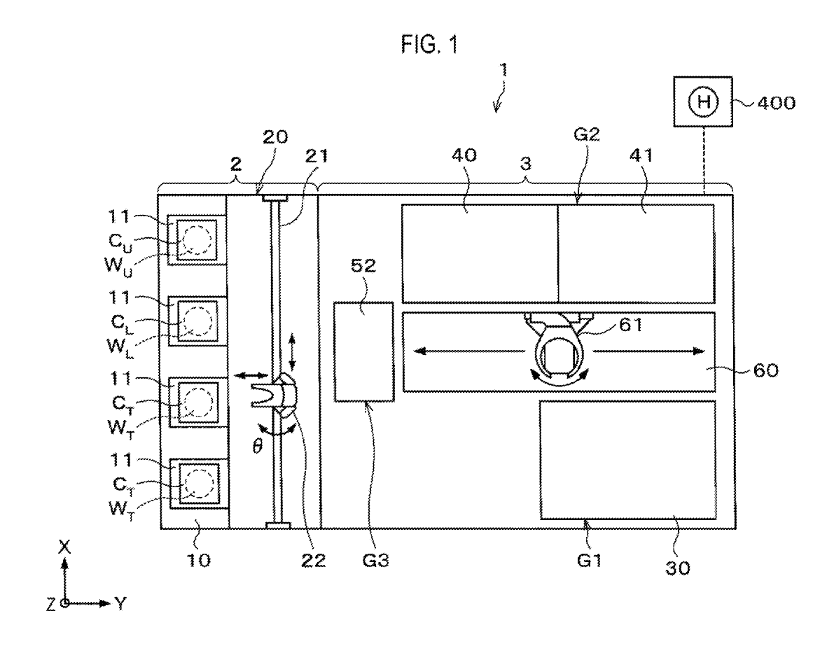

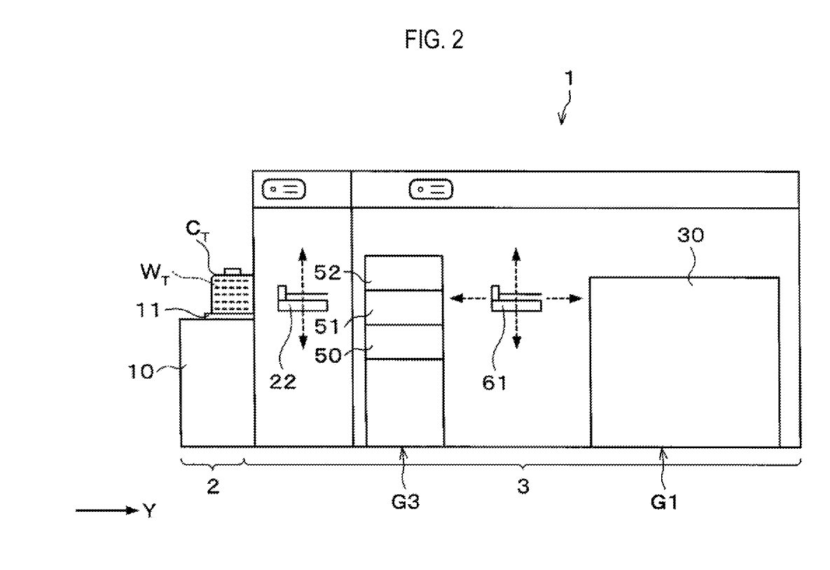

Embodiments of the present disclosure will now be described in detail with reference to the drawings. FIG. 1 is a plan view showing a general configuration of a bonding system 1 according to an embodiment. FIG. 2 is a side view showing a general internal configuration of the bonding system 1.

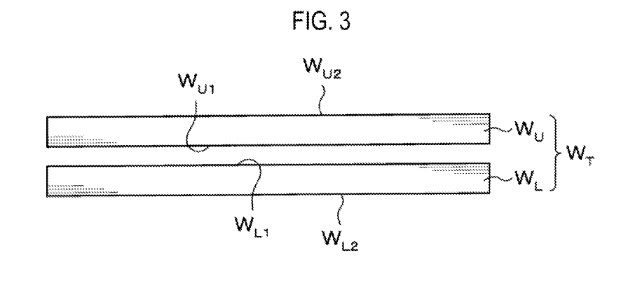

The bonding system 1 is used to bond two substrates, for example, wafers W_{U} and W_{L}, together, as shown in FIG. 3. In the following description, a wafer arranged in the upper side is referred to as an “upper wafer W_{U}” and a wafer arranged in the lower side is referred to as a “lower wafer W_{L}.” In addition, a bonding surface to which the upper wafer W_{U} bonds lower wafer W_{L} is referred to as a “front surface W_{U1},” whereas a surface opposite the front surface W_{U1} is referred to as a “rear surface W_{U2}.” Similarly, a bonding surface to which the lower wafer W_{L} bonds upper wafer W_{U} is referred to as a “front surface W_{L1},” whereas a surface opposite the front surface W_{L1} is referred to as a “rear surface W_{L2}.” In addition, in the bonding system 1, an overlapped wafer W_{T} serving as an overlapped substrate is formed by bonding the upper wafer W_{U} and the lower wafer W_{L}.

As shown in FIG. 1, the bonding system 1 includes a carry-in/carry-out station 2 for carrying in/out cassettes C_{U}, C_{L} and C_{T} to accommodate a plurality of wafers W_{U} and W_{L} and a plurality of overlapped wafers W_{T}, respectively and a processing station 3 equipped with various processing devices to perform predetermined processes for the wafers W_{U} and W_{L} and the overlapped wafers W_{T}. Stations 2 and 3 are integrated.

The carry-in/carry-out station 2 is provided with a cassette loading table 10 including a plurality of (for example, four) cassette loading plates 11 lined up in a horizontal X direction (the vertical direction in FIG. 1). When the cassettes C_{U}, C_{L} and C_{T} are carried in/out of the bonding system 1, the cassettes C_{U}, C_{L} and C_{T} can be loaded on the cassette loading plates 11. In this manner, the carry-in/carry-out station 2 is configured to hold the plurality of upper wafers W_{U}, the plurality of lower wafers W_{L} and the plurality of overlapped wafers W_{T}. In addition, the number of cassette loading plates 11 is not limited to four as configured in this embodiment but may be arbitrarily set. In addition, one cassette may be used for collecting abnormal wafers. That is, this cassette is a cassette capable of separating a wafer having abnormal bonding of an upper wafer W_{U} and a lower wafer W_{L} from a normal overlapped wafer W_{T}. In this embodiment, one of the plurality of cassettes C_{T} is used for collecting abnormal wafers and other cassettes C_{T} are used for accommodation of normal overlapped wafers W_{T}.

The carry-in/carry-out station 2 includes a wafer transfer part 20 disposed adjacent to the cassette loading table 10. The wafer transfer part 20 is provided with a wafer transfer device 22 movable over a transfer path 21 extending along the X direction. The wafer transfer device 22 can be moved in a vertical direction (X direction) or rotated about a vertical axis (A direction). The wafer transfer device 22 can transfer the wafers W_{U} and W_{L} and the overlapped wafers W_{T} between the cassettes C_{U}, C_{L} and C_{T} on the respective cassette loading plates 11 and an inspection device 50 of a third process block G3 of a processing station (which will be described later), and transition devices 51 and 52.

The processing station 3 is provided with a plurality of (for example, three) processing blocks G1, G2 and G3 having various devices. For example, the first processing block G1 is provided in the front side of the processing station 3 (in the negative X direction in FIG. 1) and the second processing block G2 is provided in the rear side of the processing station 3 (in the positive X direction in FIG. 1). In addition, the third processing block G3 is provided in the carry-in/carry-out station 2 side of the processing station 3 (in the negative Y direction in FIG. 1).

For example, a surface modifying device 30 to modify the surfaces W_{U1} and W_{L1} of the wafers W_{U} and W_{L} is arranged in the first processing block G1. In this embodiment, the surface modifying device 30 cuts a SiO₂ bonding in the surfaces W_{U1} and W_{L1} of the wafers W_{U} and W_{L} into a single-bonding SiO and then modifies the surfaces W_{U1} and W_{L1} of the wafers W_{U} and W_{L} so that they can be easily hydrophilized.

For example, in the second block G2 are arranged a surface hydrophilizing device 40 to hydrophilize and clean the surfaces W_{U1} and W_{L1} of the wafers W_{U} and W_{L} with, for example, pure water and a bonding device 41 to bond the wafers W_{U} and W_{L} together, in this order from the carry-in/carry-out station 2 in the horizontal Y direction.

For example, in the third block G3 are arranged the inspection device 50 to inspect the interior of the overlapped wafers W_{T}, the transition devices 51 and 52 of the wafers W_{U} and W_{L} and the overlapped wafers W_{T}, in an ascending order in three stages, as shown in FIG. 2.

As shown in FIG. 1, a wafer transfer zone 60 serving as a substrate transfer zone is formed in a region surrounded by the first to the third processing blocks G1 to G3. A wafer transfer device 61 may be arranged in the wafer transfer zone 60.

The wafer transfer device 61 has a transfer arm which can move along, for example, a vertical direction (Z direction) and a horizontal direction (X direction and Y direction) and rotate about a vertical axis. The wafer transfer device 61 can move in the wafer transfer zone 60 and transfer the wafers W_{U} and W_{L} and the overlapped wafers W_{T} to particular devices in the first to the third processing blocks G1, G2 and G3.

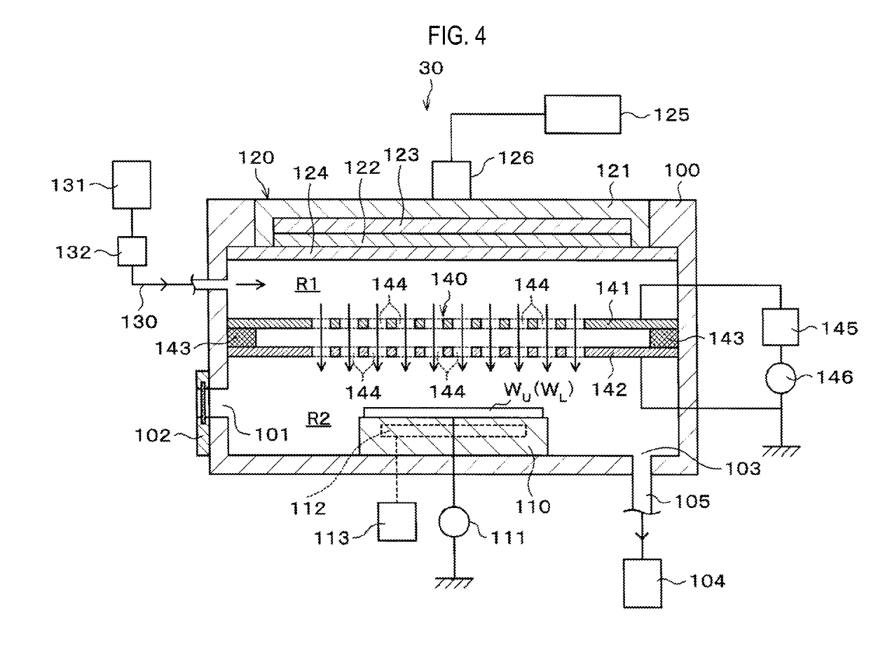

Next, a configuration of the above-mentioned surface modifying device 30 will be described. The surface modifying device 30 has a processing vessel 100 as shown in FIG. 4. The processing vessel 100 has an opened top side in which a radial line slot antenna 120 (which will be described later) is arranged such that the processing vessel 100 has its sealed interior.

An inlet/outlet 101 for the wafers W_{U} and W_{L} is formed on a side of the processing vessel 100 facing the wafer transfer zone 60 and has a gate valve 102 disposed therein.

An intake port 103 is formed at the bottom of the processing vessel 100 and is connected with an intake pipe 105 communicating to an intake device 104 which decompresses the internal atmosphere of the processing vessel 100 to a predetermined degree of vacuum.

A loading table 110 loading the wafers W_{U} and W_{L} is disposed at the bottom of the processing vessel 100. The loading table 110 can load the wafers W_{U} and W_{L} by means of, for example, electrostatic absorption or vacuum absorption. An ion amperemeter 111 is disposed on the loading table 110. The ion amperemeter 111 measures ion current generated by ions (oxygen ions) of process gas illuminated onto the wafers W_{U} and W_{L} on the loading table 110, as will be described later.

The loading table 110 has a temperature adjusting mechanism 112 distributing, for example, a cooling medium therein. The temperature adjusting mechanism 112 is connected to a liquid temperature adjusting part 113 adjusting the temperature of the cooling medium. As the temperature of the cooling medium is adjusted by the liquid temperature adjusting part 113, the temperature of the loading table 110 can be controlled. As a result, the wafers W loaded on the loading table 110 can be kept at a predetermined temperature.

Elevation pins (not shown) to support and elevate the wafers W_{U} and W_{L} from below are disposed below the loading table 110. The elevation pins are configured to be inserted from the top of the loading table 110 into through-holes (not shown) formed in the loading table 110be penetrated.

The radial line slot antenna (RLSA) 120 to supply a microwave for plasma generation is disposed in the opened top side of the processing vessel 100. The radial line slot antenna 120 has an antenna body 121 whose bottom side is opened. A passage (not shown) distributing, for example, the cooling medium is formed within the antenna body 121.

The opened bottom side of the antenna body 121 has a plurality of slots formed therein and is provided with a slot plate 122 serving as an antenna. The slot plate 122 is made of conductive material such as, for example, copper, aluminum, nickel or the like. A phase delay plate 123 is formed on the slot plate 122 in the antenna body 121. The phase delay plate 123 is made of low loss dielectric material such as, for example, quartz, alumina, aluminum nitride or the like.

A microwave transmitting plate 124 is disposed below the antenna body 121 and the slot plate 122. The microwave transmitting plate 124 is arranged to seal the processing vessel 100 by means of sealing material (not shown) such as, for example, an O-ring or the like. The microwave transmitting plate 124 is made of a dielectric such as, for example, quartz, Al₂O₃ or the like.

A coaxial waveguide 126 communicating to a microwave oscillator 125 is connected to the top of the antenna body 121. The microwave oscillator 125 is provided outside the processing vessel 100 and can oscillate a microwave having a predetermined frequency, for example, 2.5 GHz, for the radial line slot antenna 120.

With this configuration, the microwave oscillated from the microwave oscillator 125 propagates into the radial line slot antenna 120, is compressed into a shorter wavelength by means of the phase delay plate 123, is rendered into a circularly-polarized wave by means of the slot plate 122, and is emitted into the processing vessel 100 through the microwave transmitting plate 124.

A gas supply pipe 130 supplying oxygen gas as process gas into the processing vessel 100 is connected to a side of the processing vessel. The gas supply pipe 130 is arranged over an ion passing structure 140 (which will be described later) and supplies oxygen gas into a plasma generation region R1 in the processing vessel 100. A gas source 131 storing the oxygen gas connected to the gas supply pipe 130 through a group of gas supply devices 132. The group of gas supply devices 132 including a valve, a flow rate regulator and so on which controls a flow of oxygen gas.

The ion passing structure 140 is interposed between the loading table 110 in the processing vessel 100 and the radial line slot antenna 120. That is, the ion passing structure 140 is disposed to partition the interior of the processing vessel 100 into the plasma generation region R1 where the oxygen gas supplied from the gas supply pipe 130 is plasmalized by the microwave emitted from the radial line slot antenna 120 and a process region R2 where oxygen ions generated in the plasma generation region R1 are used to modify the surfaces W_{U1} and W_{L1} of the wafers W_{U} and W_{L} on the loading table 110.

The ion passing structure 140 has a pair of electrodes 141 and 142. In the following description, in some cases, an electrode arranged in the upper part is referred to as an upper electrode 141 and an electrode arranged in the lower part is referred to as a lower electrode 142. An insulating material 143 to electrically insulate the pair of electrodes 141 and 142 from each other is interposed between the pair of electrodes 141 and 142.

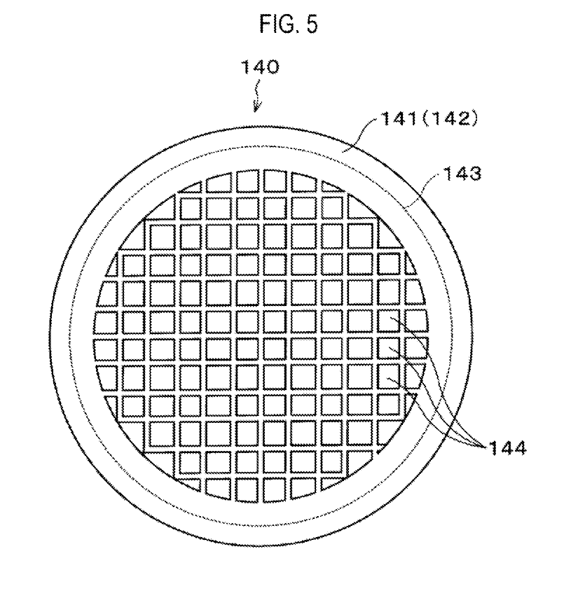

Each of the electrodes 141 and 142 is in a circular shape with diameter larger than that of the wafers W_{U} and W_{L} when viewed from the top, as shown in FIGS. 4 and 5. In addition, each of the electrodes 141 and 142 has a plurality of openings 144 through which the oxygen ions pass from the plasma generation region R1 into the process region R2. These openings 144 are arranged in the form of, for example, a lattice. The form and arrangement of the openings 144 are not limited to this embodiment but may be arbitrarily set.

Here, it is preferable that the dimension of each of the openings 144 is, for example, set to be shorter than a wavelength of a microwave emitted from the radial line slot antenna 120. This allows the microwave supplied from the radial line slot antenna 120 to be reflected by the ion passing structure 140, thereby preventing the microwave from being introduced into the process region R2. As a result, the wafers W_{U} and W_{L} on the loading table 110 can be prevented from being directly exposed to the microwave, thereby preventing the wafers W_{U} and W_{L} from being damaged by the microwave.

A power supply 145 to apply a predetermined voltage across the pair of electrodes 141 and 142 is connected to the ion passing structure 140. The predetermined voltage applied by the power supply 145 is controlled by a controller 400 which will be described later, and its maximum value is, for example, 1 KeV. In addition, an amperemeter 146 to measure current flowing between the pair of electrodes 141 and 142 is connected to the ion passing structure 140.

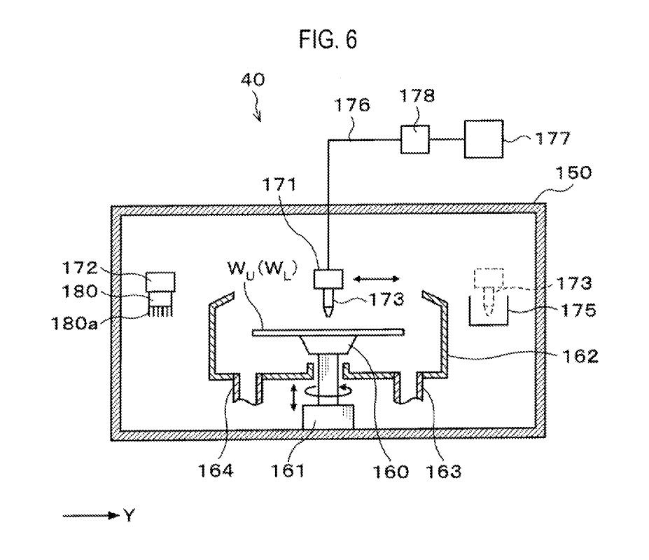

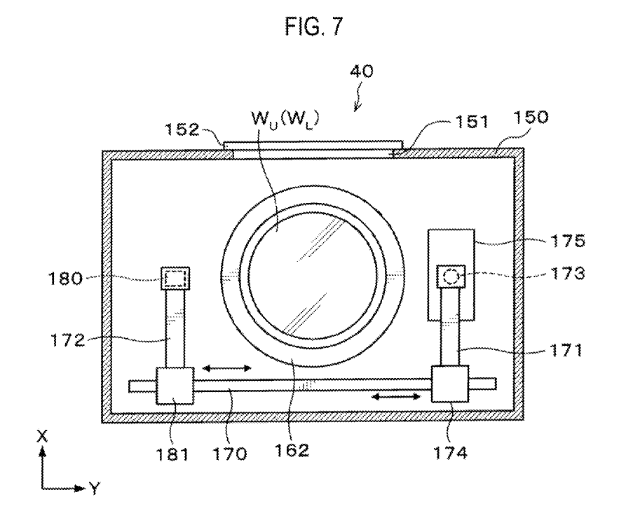

Next, a configuration of the above-mentioned surface hydrophilizing device 40 will be described. The surface hydrophilizing device 40 has a sealable processing vessel 150, as shown in FIG. 6. An inlet/outlet 151 of the wafers W_{U} and W_{L} is formed on a side of the processing vessel 150 facing the wafer transfer zone 60 and an opening/closing shutter 152 is provided in the inlet/outlet 151, as shown in FIG. 7.

A spin chuck 160 to hold and rotate the wafers W_{U} and W_{L} is disposed in the middle of the processing vessel 150, as shown in FIG. 6. The spin chuck 160 has a flat top side provided with an attraction port (not shown) for attracting the wafers W_{U} and W_{L}. The wafers W_{U} and W_{L} can be adhered and held on the spin chuck 160 by an attracting force from the attraction port.

The spin chuck 160 has a chuck driver 161 including, for example, a motor or the like and can be rotated at a predetermined speed by means of the chuck driver 161. The chuck driver 161 is provided with an elevating driving source, such as, for example, a cylinder or the like, to allow the spin chuck 160 to be elevated.

A cup 162 to receive and collect liquid scattering or dropping from the wafers W_{U} and W_{L} is disposed around the spin chuck 160. A discharge pipe 163 and an exhaust pipe 164 are connected to the bottom of the cup 162. The discharge pipe 163 discharges the collected liquid and the exhaust pipe 164 purges and exhausts the internal atmosphere of the cup 162.

As shown in FIG. 7, a rail 170 extending in the Y direction (the horizontal direction in FIG. 7) is formed on the negative X direction of the cup 162 (the downward direction in FIG. 7). In this embodiment, the rail 170 extends from the outside of the negative Y direction of the cup 162 (the left direction in FIG. 7) to the outside of the positive Y direction (the right direction in FIG. 7). A nozzle arm 171 and a scrub arm 172 may be attached to the rail 170.

A pure water nozzle 173 to supply pure water to the wafers W_{U} and W_{L} is supported by the nozzle arm 171, as shown in FIGS. 6 and 7. The nozzle arm 171 can move over the rail 170 by means of a nozzle driver 174 shown in FIG. 7. This allows the pure water nozzle 173 to move from a standby section 175 located at the outside facing the positive Y direction of the cup 162 to a location above the center of the wafers W_{U} and W_{L} in the cup 162. The pure water nozzle 173 may further move over the wafers W_{U} and W_{L} in the radial direction of the wafers W_{U} and W_{L}. In addition, the nozzle arm 171 can be elevated by the nozzle driver 174 to adjust the height of the pure water nozzle 173.

A supply pipe 176 to supply the pure water to the pure water nozzle 173 is connected to the pure water nozzle 173, as shown in FIG. 6. The supply pipe 176 is connected to a pure water source 177 storing the pure water. The supply pipe 176 is provided with a group of supply devices 178 including a valve, a flow rate regulator and so on to control a flow of pure water.

A scrub cleaning tool 180 is supported to the scrub arm 172. For example, a plurality of a thread-like or sponge-like brush 180a is formed on the leading end of the scrub cleaning tool 180. The scrub arm 172 can move over the rail 170 by means of a cleaning tool driver 181 shown in FIG. 7 and allows the scrub cleaning tool 180 to move from the outside of the side of the negative Y direction of the cup 162 to a location above the center of the wafers W_{U} and W_{L} in the cup 162. Further, the scrub arm 172 can move over the wafers W_{U} and W_{L} in the radial direction of the wafers W_{U} and W_{L}. In addition, the scrub arm 172 can be elevated by the cleaning tool driver 181 to adjust the height of the scrub cleaning tool 180.

While it has been illustrated in the above that the pure water nozzle 173 and the scrub cleaning tool 180 are supported to their respective arms, they may be supported to the same arm. In addition, pure water may be supplied from the scrub cleaning tool 180 with the pure water nozzle 173 omitted in this embodiment. In addition, the cup 162, omitted in this embodiment, with the discharge pipe to discharge the liquid and the exhaust pipe to exhaust the internal atmosphere of the processing vessel 150 may be connected to the bottom of the processing vessel 150. In addition, the surface hydrophilizing device 40 as configured above may be provided with an antistatic ionizer (not shown).

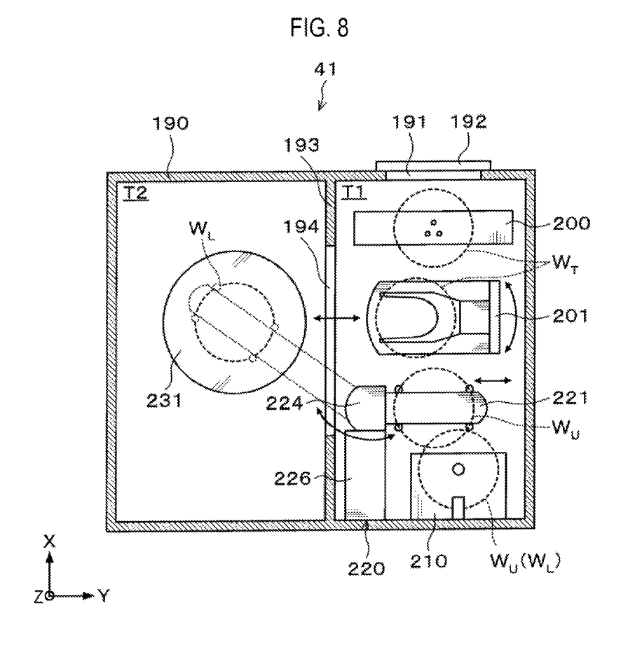

Next, a configuration of the above-mentioned bonding device 41 will be described. The bonding device 41 has a sealable processing vessel 190 as shown in FIG. 8. An inlet/outlet 191 of the wafers W_{U} and W_{L} and the overlapped wafers W_{T} is formed on a side of the processing vessel 190 facing the wafer transfer zone 60, and an opening/closing shutter 192 is provided in the inlet/outlet 191.

The interior of the processing vessel 190 is partitioned into a transfer region T1 and a process region T2 by an inner wall 193. The inlet/outlet 191 is formed on a side of the processing vessel 190 in the transfer region T1. In addition, an inlet/outlet 194 of the wafers W_{U} and W_{L} and the overlapped wafers W_{T} is also formed on the inner wall 193.

A transition 200 to temporarily load the wafers W_{U} and W_{L} and the overlapped wafers W_{T} is formed in the positive X direction of the transfer region T1. The transition 200 is, for example, formed into two-stages and can load any two of the wafers W_{U}, W_{L} and the overlapped wafers W_{T}, simultaneously.

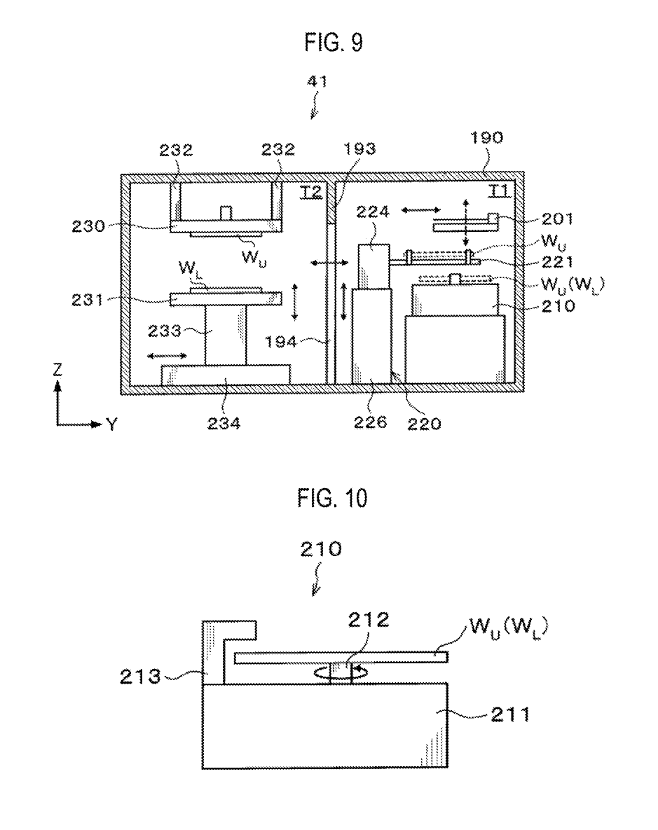

A wafer transfer mechanism 201 is provided in the transfer region T1. The wafer transfer mechanism 201 has a transfer arm which can be move along a vertical direction (Z direction) and a horizontal direction (X direction and Y direction) and rotate about a vertical axis, as shown in FIGS. 8 and 9. In addition, the wafer transfer mechanism 201 can transfer the wafers W_{U} and W_{L} and the overlapped wafers W_{T} within the transfer region T1 or between the transfer region T1 and the process region T2.

A positioning mechanism 210 to adjust the horizontal direction of the wafers W_{U} and W_{L} is provided in the negative X direction of the transfer region T1. As shown in FIG. 10, the positioning mechanism 210 has a base 211, a holding unit 212 to attract, hold and rotate the wafers W_{U} and W_{L}, and a detector 213 to detect the position of notches of the wafers W_{U} and W_{L}. While the holding unit 212 rotates the wafers W_{U} and W_{L} attracted and held on the holding unit 212, detector 213 detects the position of the notches of the wafers W_{U} and W_{L}. The positioning mechanism 210 adjusts the position of the notches and hence the horizontal direction of the wafers W_{U} and W_{L}

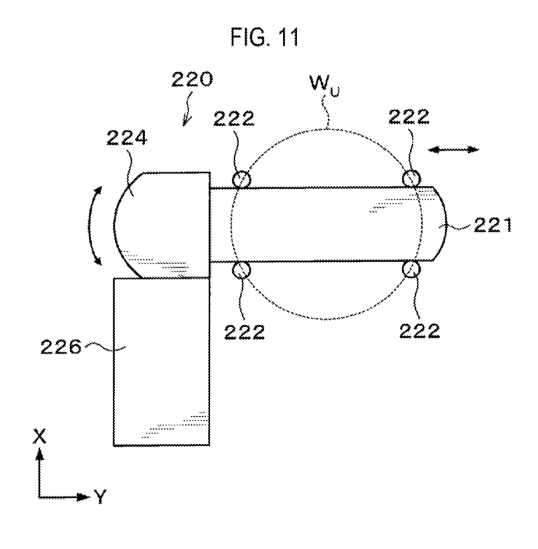

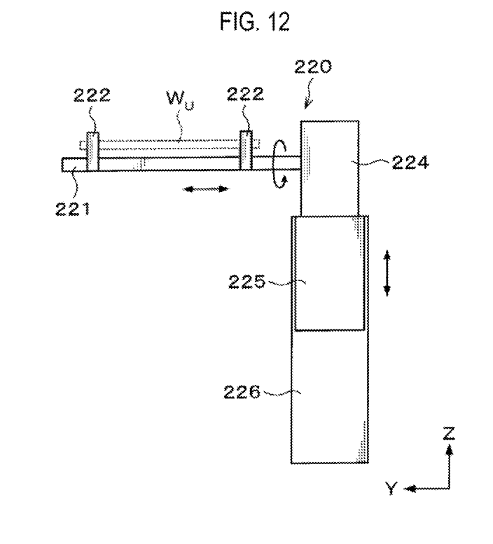

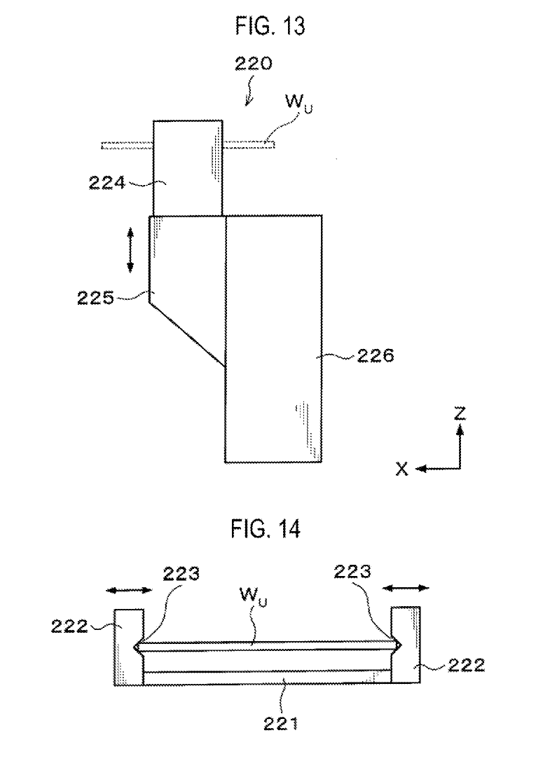

In addition, an inverting mechanism 220 to invert the front and rear surfaces of the upper wafers W_{U} is provided in the transfer region T1. The inverting mechanism 220 has a holding arm 221 to hold the upper wafers W_{U}, as shown in FIGS. 11 to 13. The holding arm 221 extends in the horizontal direction (the Y direction in FIGS. 11 and 12). In addition, the holding arm 221 is provided with four holding members 222 to hold the upper wafers W_{U}. The holding members 222 are configured to move in the horizontal direction with respect to the holding arm 221, as shown in FIG. 14. Cutouts 223 to hold the circumference of the upper wafers W_{U} are formed on sides of the holding members 222. These holding members 222 can hold the upper wafers W_{U} interposed therebetween.

The holding arm 221 is supported by a first driver 224 including, for example, a motor or the like, as shown in FIGS. 11 to 13. The holding arm 221 can be rotated around a horizontal axis by means of the first driver 224. In addition, the holding arm 221 can be moved in the horizontal direction (the Y direction in FIGS. 11 and 12) while being rotated around the first driver 224. A second driver 225 including, for example, a motor or the like is disposed below the first driver 224. The first driver 224 can be moved by means of the second driver 225 in the vertical direction along a support 226 extending in the vertical direction. Thus, the upper wafers W_{U} held on the holding members 222 can be rotated around the horizontal axis and moved in the vertical and horizontal directions by means of the first driver 224 and the second driver 225. In addition, the upper wafers W_{U} held on the holding members 222 can be rotated around the first driver 224 and moved between the positioning mechanism 210 and an upper chuck 230 which will be described later.

As shown in FIGS. 8 and 9, the upper chuck 230 to attract and hold the upper wafers W_{U} on its bottom side and a lower chuck 231 to load, attract and hold the lower wafers W_{L} on its top side are provided in the process region T2. The lower chuck 231 is disposed below the upper chuck 230 in an opposing manner. That is, the upper wafers W_{U} held on the upper chuck 230 and the lower wafers W_{L} held on the lower chuck 231 can be arranged to face each other.

As shown in FIG. 9, the upper chuck 230 is supported by a support member 232 attached to the ceiling of the processing vessel 190. The support member 232 supports the circumference of the top side of the upper chuck 230. A chuck driver 234 is provided via a shaft 233 below the lower chuck 231. The lower chuck 231 can be elevated in the vertical direction and moved in the horizontal direction by means of the chuck driver 234. In addition, the lower chuck 231 can be rotated around a vertical axis by means of the chuck driver 234. In addition, elevation pins (not shown) to support and elevate the lower wafers W_{L} from below are disposed below the lower chuck 231. The elevation pins are configured to be inserted from the top of the lower chuck 231 into through-holes (not shown) formed on the lower chuck 231 be penetrated.

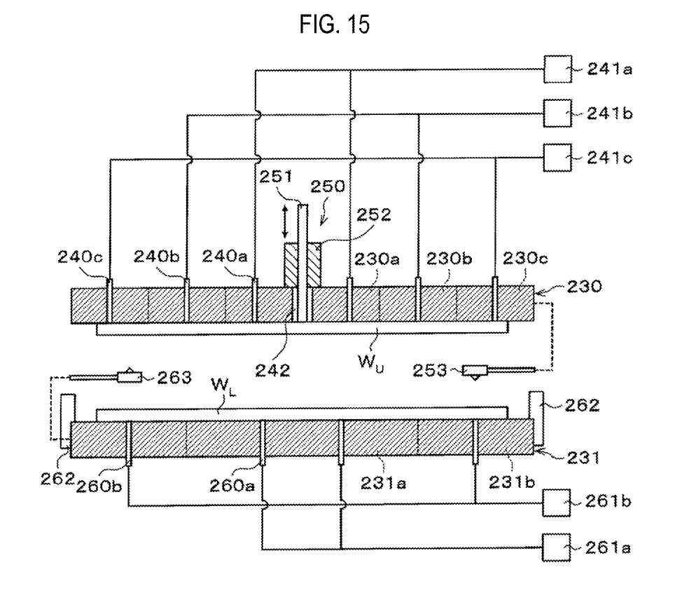

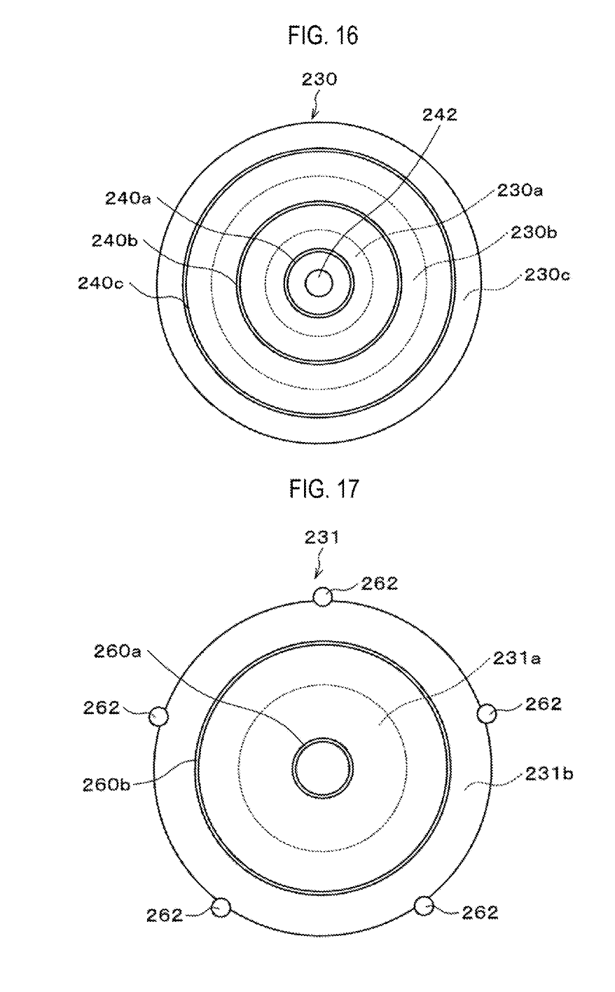

As shown in FIG. 15, the upper chuck 230 is partitioned into a plurality of (for example, 3) regions 230a, 230b and 230c. These regions 230a, 230b and 230c are formed in this order from the center toward the circumference of the upper chuck 230, as shown in FIG. 16. When viewed from the top, the region 230a has a circular shape and the regions 230b and 230c have an annular shape. The regions 230a, 230b and 230c have their respective attracting pipes 240a, 240b and 240c to attract and hold the upper wafers W_{U}, as shown in FIG. 15. Different vacuum pumps 241a, 241b and 241c are connected to the attracting pipes 240a, 240b and 240c, respectively. Accordingly, the upper chuck 230 is configured to purge the upper wafers W_{U} in each of the regions 230a, 230b and 230c.

In the following description, the above three regions 230a, 230b and 230c may be called a first region 230a, a second region 230b and a third region 230c, respectively. In addition, the attracting pipes 240a, 240b and 240c may be called a first attracting pipe 240a, a second attracting pipe 240b and a third attracting pipe 240c, respectively. In addition, the vacuum pumps 241a, 241b and 241c may be called a first vacuum pump 241a, a second vacuum pump 241b and a third vacuum pump 241c, respectively.

A through-hole 242 passing through the upper chuck 230 in its thickness direction is formed on the center of the upper chuck 230. The center of the upper chuck 230 corresponds to the center of the upper wafers W_{U} attracted and held on the upper chuck 230. A pressing pin 251 of a pressing member 250 which will be described later is configured to be inserted into the through-hole 242.

The pressing member 250 to press the center of the upper wafers W_{U} is disposed on the top side of the upper chuck 230. The pressing member 250 is of a cylindrical shape and has the pressing pin 251 and an outer tube 252 serving as a guide when the pressing pin 251 is elevated. The pressing pin 251 can be inserted into the through-hole 242 and vertically elevated by means of a driver (not shown) including, for example, a motor or the like. In addition, the pressing member 250 can press the center of the upper wafers W_{U} and the center of the lower wafers W_{L} in contact when the wafers W_{U} and W_{L} are bonded together, which will be described later.

The upper chuck 230 is provided with an upper imaging member 253 to image the surfaces W_{L1} of the lower wafers W_{L}. An example of the upper imaging member 253 may include a wide-angle CCD camera. The upper imaging member 253 may be disposed under the upper chuck 230.

The lower chuck 231 is partitioned into a plurality of (for example, two) regions 231a and 231b, as shown in FIG. 17. These regions 231a and 231b are formed in this order from the center toward the circumference of the lower chuck 231. When viewed from the top, the region 231a has a circular shape and the region 231b has an annular shape. The regions 231a and 231b have their respective attracting pipes 260a and 260b to attract and hold the lower wafers W_{L}, as shown in FIG. 15. Different vacuum pumps 261a and 261b are connected to the attracting pipes 260a and 260, respectively. Accordingly, the lower chuck 231 is configured to purge the lower wafers W_{L} in each of the regions 231a and 231b.

On the circumference of the lower chuck 231 are disposed stopper members 262 to prevent the wafers W_{U} and W_{L} and the overlapped wafers W_{T} from leaping over or slipping from the lower chuck 231. The stopper members 262 extend in the vertical direction in such a manner that their top sides are positioned at least above the overlapped wafers W_{T} on the lower chuck 231. In addition, the stopper members 262 are disposed on a plurality of (for example, five) place located on the circumference of the lower chuck 231, as shown in FIG. 17.

The lower chuck 231 is provided with a lower imaging member 263 to image the surfaces W_{U1} of the upper wafers W_{U}, as shown in FIG. 15. An example of the lower imaging member 263 may include a wide-angle CCD camera. The lower imaging member 263 may be disposed over the lower chuck 231.

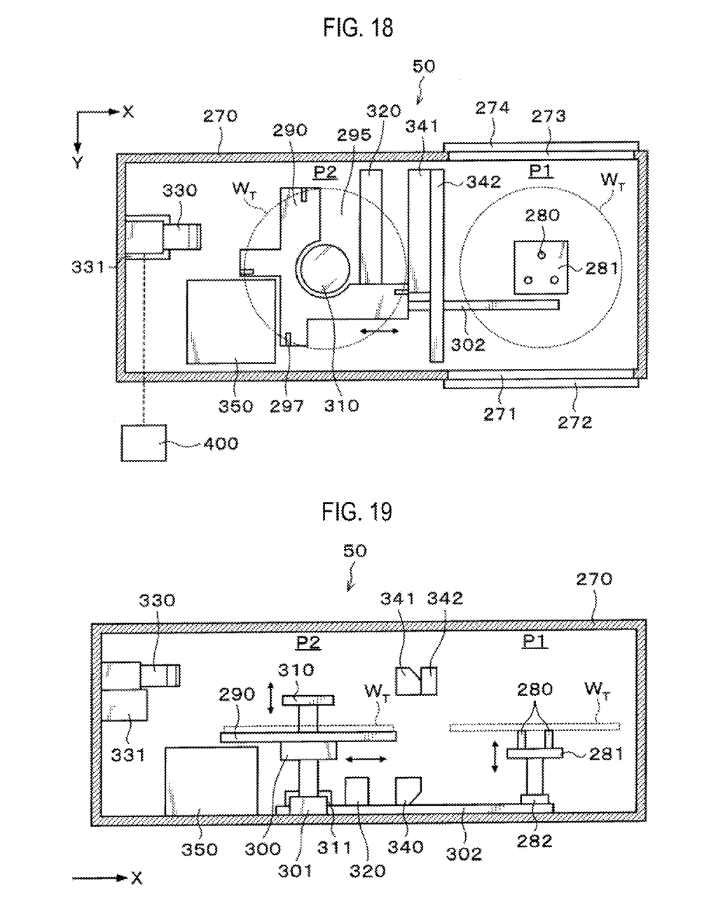

Next, a configuration of the above inspection device 50 will be described. The inspection device 50 has a processing vessel 270, as shown in FIGS. 18 and 19. An inlet/outlet 271 of an overlapped wafer W_{T} is formed on a side of the processing vessel 270 facing the wafer transfer zone 60, and an opening/closing shutter 272 is provided in the inlet/outlet 271. In addition, an inlet/outlet 273 of the overlapped wafer W_{T} is formed on a side of the processing vessel 270 facing the carry-in/carry-out station 2 and an opening/closing shutter 274 is provided in the inlet/outlet 273.

On the side of the inlet/outlets 271 and 273 within the processing vessel 270 (in the positive X direction in FIGS. 18 and 19) are provided elevation pins 280 to exchange the overlapped wafer W_{T} with the external wafer transfer device 61 and exchange the overlapped wafer W_{T} with a first holding unit 290 which will be described later. In this example, three elevation pins 280 are provided over a holding member 281. The elevation pins 280 can be elevated by means of an elevation driver 282 including, for example, a motor or the like.

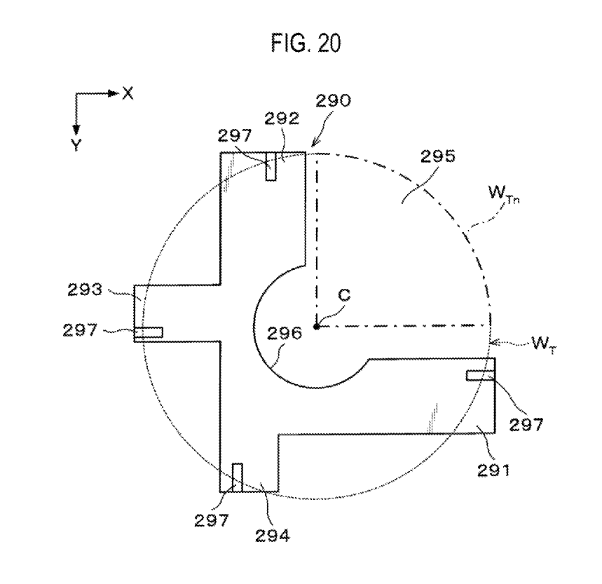

The first holding unit 290 to hold the rear surfaces of the overlapped wafer W_{T} is provided within the processing vessel 270. As shown in FIG. 20, the first holding unit 290 has four supporting members 291 to 294 which are substantially rectangular when viewed from the top. These supporting members 291 to 294 extend in a direction perpendicular to adjacent supporting members when viewed from the top. That is, the supporting members 291 and 293 extend in the X direction and the supporting members 292 and 294 extend in the Y direction in FIG. 20. In the following description, the supporting members 291 to 294 may be called a first supporting member 291, a second supporting member 292, a third supporting member 293 and a fourth supporting member 294, respectively.

In the first holding unit 290, the overlapped wafer W_{T} is held such that its center C is positioned between the first supporting member 291 and the second supporting member 292. In addition, a cutout 295 to expose a quarter of the rear surface of the overlapped wafer W_{T} is formed between the first supporting member 291 and the second supporting member 292. In FIG. 20, the exposed quarter of the rear surface of the overlapped wafer W_{T} is indicated by an alternate long and short dash line. In the following description, the overlapped wafer W_{T} may be sometimes called an overlapped wafer W_{T}. (n is an integer of 1 to 4). In addition, a recess 296 curved along an edge of a second holding unit 310, which will be described later, is formed in a side of the first supporting member 291 and the second supporting member 292.

In addition, holding members 297 to hold the rear surface of the overlapped wafer W_{T} are formed on leading ends of the respective supporting members 291 to 294. These holding members 297 are arranged such that an angle defined by connecting adjacent holding members 297 to the center of the overlapped wafer W_{T} is smaller than 120 degrees. This allows the overlapped wafer W_{T} to be stably held to the first holding unit 290. In addition, an example of each holding member 297 may include a resin O-ring or a support pin. For the resin O-ring, the holding members 297 hold the rear surface of the overlapped wafer W_{T} by means of a friction between the second supporting member 292 and the rear surface of the overlapped wafer W_{T}.

The first holding unit 290 is provided with a driver 301 via a member 300, as shown in FIG. 19. The driver 301 contains, for example, a motor (not shown). A rail 302 extending in the X direction in FIGS. 18 and 19 is provided in the bottom of the processing vessel 270. The driver 301 is attached to the rail 302. The first holding unit 290 (or the driver 301) can be moved between an exchange position P1 at which the overlapped wafer W_{T} is exchanged with the elevation pins 280 and a rotation position P2 at which the overlapped wafer W_{T} is rotated by the second holding unit 310 which will be described later, along the rail 302. The driver 301 and the rail 302 form a moving mechanism recited in the present disclosure.

The second holding unit 310 to hold and rotate the overlapped wafer W_{T} is provided within the processing vessel 270. The second holding unit 310 is disposed at the above-mentioned rotation position P2. The second holding unit 310 has a flat top side provided with, for example, an attraction port (not shown) for attracting the overlapped wafer W_{T}. The overlapped wafer W_{T} can be adhered and held on the second holding unit 310 by an attracting force from the attracting port.

The second holding unit 310 is attached with a driver 311 including, for example, a motor or the like. The second holding unit 310 can be rotated by means of the driver 311. The driver 311 is provided with an elevation driving source such as, for example, a cylinder or the like to elevate the second holding unit 310. In addition, when the first holding unit 290 is at the rotation position P2, the second holding unit 310 does not interfere with the first holding unit 290 by virtue of the recess 296 formed in the first holding unit 290 even when the second holding unit 310 is elevated.

Within the processing vessel 270 is provided an infrared irradiator 320 to irradiate the rear surface of the overlapped wafer W_{T} on the first holding unit, exposed from the cutout 295 (i.e., the overlapped wafer W_{Tn}), with an infrared ray. The infrared irradiator 320 is arranged between the exchange position P1 and the rotation position P2 below the first holding unit 290 and the second holding unit 310. In addition, the infrared irradiator 320 extends in the Y direction to be longer than at least the width of the overlapped wafer W_{T}. A wavelength of the infrared ray emitted from the infrared irradiator is 1100 nm to 2000 nm. The infrared ray having such a wavelength transmits through the overlapped wafer W_{T}.

Within the processing vessel 270 is also provided an image pickup unit 330 to receive the infrared ray emitted from the infrared irradiator 320 and pick up an image of the rear surface of the overlapped wafer W_{T} held on the first holding unit 290, exposed from the cutout 295, in division. Namely, the image pickup unit 330 picks up an image of the overlapped wafer W_{T}. An example of the image pickup unit 330 may include an infrared camera. The image pickup unit 330 is disposed in a side of the negative X direction from the rotation position P2, that is, in the end of the negative X direction of the processing vessel 270, above the first holding unit 290 and the second holding unit 310. In addition, the image pickup unit 330 is supported by a support member 331. The image pickup unit 330 is connected with the controller 400 which will be described later. Images of the overlapped wafer W_{Tn} picked up by the image pickup unit 330 are output to the controller 400 in which the images are combined into a single whole image of the overlapped wafer W_{T}.

Within the processing vessel 270 are provided direction changers 340 and 341 to change a direction of an infrared traveling path between the infrared irradiator 320 and the image pickup unit 330. The direction changers 340 and 341 are arranged to face each other in the exchange position (P1) side from the infrared irradiator 320 (in the positive X direction side in FIGS. 18 and 19). The first direction changer 340 is disposed below the first holding unit 290 and the second holding unit 310, whereas the second direction changer 341 is disposed above the first holding unit 290 and the second holding unit 310. In addition, the first and second direction changers 340 and 341 are arranged to extend in the Y direction. In addition, the second direction changer 341 is supported to a support member 342 extending in the Y direction.

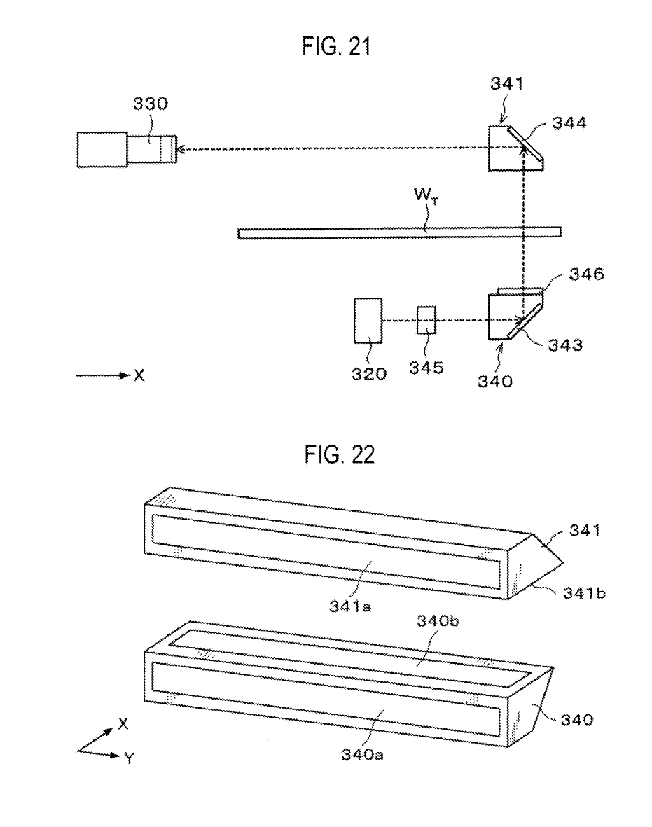

As shown in FIG. 21, a first reflecting mirror 343 is provided within the first direction changer 340. The first reflecting mirror 343 is disposed to be inclined by 45 degrees from the horizontal direction. The infrared ray from the infrared irradiator 320 is reflected by the first reflecting mirror 343 and then travels in the vertical direction. In addition, as shown in FIG. 22, openings 340a and 340b through which the infrared ray passes are formed in the lateral side and top side of the first direction changers 340, respectively.

Similarly, as shown in FIG. 21, a second reflecting mirror 344 is provided within the second direction changer 341. The second reflecting mirror 344 is disposed to be inclined by 45 degrees from the horizontal direction. The infrared ray from the first direction changer 340 is reflected by the second reflecting mirror 344 and then travels in the horizontal direction. In addition, as shown in FIG. 22, openings 341a and 341b through which the infrared ray passes are formed in the lateral side and bottom of the second direction changer 341, respectively.

In addition, as shown in FIG. 21, a cylindrical lens 345 to collect the infrared ray irradiated onto the overlapped wafer W_{T} is interposed between the infrared irradiator 320 and the first direction changer 340. In addition, a diffusing plate 346 to make the infrared ray collected by cylindrical lens 345 evenly distributed throughout the plane of the overlapped wafer W_{T} is disposed on the top of the first direction changer 340.

With this configuration, the infrared ray emitted from the infrared irradiator 320 transmits the overlapped wafer W_{T} through the cylindrical lens 345, the first reflecting mirror 343 and the diffusing plate 346 and then is received in the image pickup unit 330 through the second reflecting mirror 344.

As shown in FIGS. 18 and 19, a position detecting mechanism 350 to detect a position of the overlapped wafer W_{T} held on the second holding unit 310 is provided within the processing vessel 270. The position detecting mechanism 350 is disposed along the third supporting member 293 and the fourth supporting member 294 of the first holding unit 290. The position detecting mechanism 350 has, for example, a CCD camera (not shown) and detects a position of a notch of the overlapped wafer W_{T} held on the second holding unit 310. The position of the notch of the overlapped wafer W_{T} can be adjusted by detecting the position of the notch by means of the position detecting mechanism 350 while rotating the second holding unit 310.

The above-configured bonding system 1 has the controller 400, as shown in FIG. 1. The controller 400 is, for example, a computer and has a program storage unit (not shown). The program storage unit stores a program to control the process of the wafers W_{U} and W_{L} and the overlapped wafers W_{T} in the bonding system 1. The program storage unit stores also a program to implement a wafer bonding process (which will be described later) in the bonding system 1 by controlling an operation of the driving system including the above-described various processing devices and transfer devices. The programs may be installed from a computer readable hard disk (HD), a flexible disk (FD), a compact disc (CD), a magneto-optical disk (MO), or a computer readable memory medium (H) such as a memory card or the like into the controller 400.

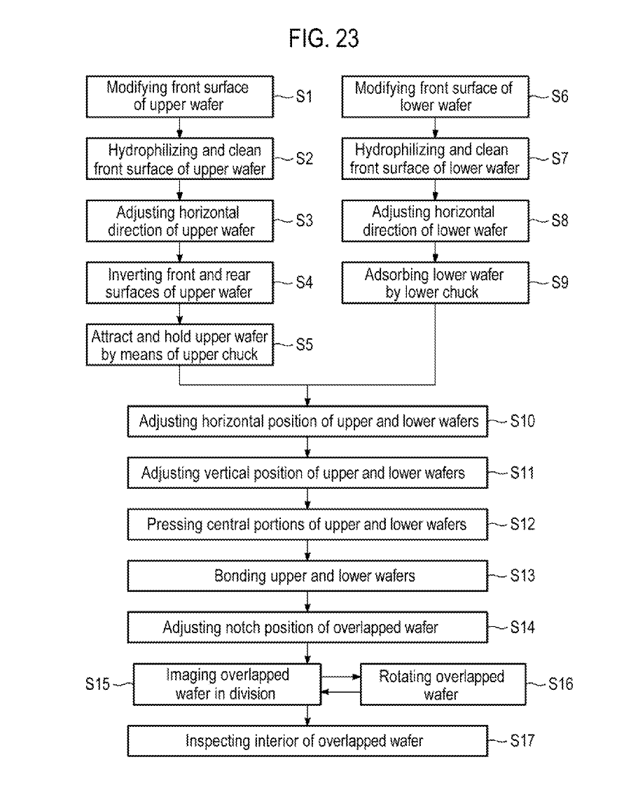

Next, a method of bonding wafers W_{U} and W_{L} and a method of inspecting an overlapped wafer WT using the above-configured bonding system 1 will be described. FIG. 23 is a flow chart illustrating main operations of the wafer bonding process.

First, a cassette C_{U} accommodating a plurality of upper wafers W_{U}, a cassette C_{L} accommodating a plurality of lower wafers W_{L}, and an empty cassette C_{T} are loaded on respective cassette loading plates 11 of the carry-in/carry-out station 2. Thereafter, the wafer transfer device 22 takes an upper wafer W_{U} out of the cassette C_{U} and transfers it to the transition device 51 of the third process block G3 of the processing station 3.

Next, the wafer transfer device 61 transfers the upper wafer W_{U} to the surface modifying device 30 of the first process block G1. The upper wafer W_{U} carried in the surface modifying device 30 is loaded on the loading table 110 from the wafer transfer device 61. Thereafter, the wafer transfer device 61 is retreated from the surface modifying device 30, and the gate valve 102 is closed. The upper wafer W_{U} loaded on the loading station 110 is maintained at a predetermined temperature, for example, 25 to 30 degrees C. by means of the temperature adjusting mechanism 112.

Thereafter, the intake device 104 is actuated to decompress the internal atmosphere of the processing vessel 100 to a predetermined degree of vacuum, for example, 67 to 333 Pa (0.5 to 2.5 Torr) through the intake port 103. Then, the internal atmosphere of the processing vessel 100 is kept at the predetermined degree of vacuum during the upper wafer W_{U} processing of, as will be described later.

Thereafter, oxygen gas is supplied from the gas supply pipe 130 toward the plasma generation region R1 within the processing vessel 100. In addition, a microwave of, for example, 2.45 GHz is emitted from the radial line slot antenna 120 toward the plasma generation region R1. This microwave emission allows the oxygen gas to be excited and plamsalized in the plasma generation region R1, which results in, for example, ionization of the oxygen gas. At this time, some microwave traveling downward is reflected by the ion passing structure 140 and stays within the plasma generation region R1, which results in highly-dense plasma generated within the plasma generation region R1.

Subsequently, in the ion passing structure 140, the power supply 145 applies a predetermined voltage to the pair of electrodes 141 and 142. Thus, the pair of electrodes 141 and 142 allows only the oxygen ions generated in the plasma generation region R1 to be introduced into the process region R2 through the opening 144 of the ion passing structure 140.

At the same time, when the voltage applied between the pair of electrodes 141 and 142 is controlled by the controller 400, energy provided to the oxygen ions passing through the pair of electrodes 141 and 142 is controlled. The energy provided to the oxygen ions is energy sufficient to cut a double bonding SiO₂ in the surface W_{U1} of the upper wafer W_{U} into a single-bonding SiO but and is set to the level such that there is no damage to the surface W_{U1}.

In addition, a value of current flowing between the pair of electrodes 141 and 142 is measured by the amperemeter 146. An amount of oxygen ions passing through the ion passing structure 140 is calculated based on the measured current value. Then, based on the calculated amount of oxygen ions passing through the ion passing structure 140, the controller 400 controls various parameters such as an amount of oxygen gas supply from the gas supply pipe 130, a voltage between the pair of electrodes 141 and 142, and the like such that the amount of oxygen ions reaches a predetermined value.

Thereafter, the oxygen ions introduced into the process region R2 are irradiated and injected onto the surface W_{U1} of the upper wafer W_{U} on the loading table 110. The irradiated oxygen ions cut a double bonding SiO₂ in the surface W_{U1} into a single-bonding SiO. In addition, since the oxygen ions are used for modification of the surface W_{U1}, the oxygen ions irradiated on the surface W_{U1} of the upper wafer W_{U} contribute to the bonding of SiO. Accordingly, the surface W_{U1} of the upper wafer W_{U} is modified (Operation S1 in FIG. 23).

Next, the upper wafer W_{U} is transferred by the wafer transfer device 61 to the surface hydrophilizing device 40 of the second process block G2. The upper wafer W_{U} carried in the surface hydrophilizing device 40 is delivered from the wafer transfer device 61 to the spin chuck 160 to attract and hold the upper wafer W_{U}.

Subsequently, the nozzle arm 171 moves the pure water nozzle 173 of the standby section 175 to a location above the upper wafer W_{U}, and at the same time, the scrub arm 172 moves the scrub cleaning tool 180 above the upper wafer W_{U}. Thereafter, pure water is supplied from the pure water nozzle 173 onto the upper wafer WU while rotating the upper wafer W_{U} by means of the spin chuck 160. Thus, a hydroxyl group (silanol group) is adhered to the surface W_{U1} of the upper wafer W_{U} modified by the surface modifying device 30. In addition, the surface W_{U1} of the upper wafer W_{U} is cleaned by the scrub cleaning tool 180 and the pure water from the pure water nozzle 173 (Operation S2 in FIG. 23). In addition, some of the pure water supplied onto the surface W_{U1} of the upper wafer W_{U} is used to hydrophilize the surface W_{U1}, as described above, to bond the wafers W_{U} and W_{L}, as will be described later. The remaining excessive pure water remains on the surface W_{U1} of the upper wafer W_{U}.

Next, the wafer transfer device 61 transfers the upper wafer W_{U} to the bonding device 41 of the second process block G2. The upper wafer W_{U} carried in the bonding device 41 is transferred by the wafer transfer mechanism 201 to the positioning mechanism 210 via the transition 200. Then, the horizontal direction of the upper wafer W_{U} is adjusted by the positioning mechanism 210 (Operation S3 in FIG. 23).

Thereafter, the upper wafer W_{U} is delivered from the positioning mechanism 210 to the holding arm 221 of the inverting mechanism 220. Subsequently, the holding arm 221 is inverted in the transfer region T1, thereby inverting the front and rear surfaces of the upper wafer W_{U} (Operation S4 in FIG. 23). That is, the front surface W_{U1} of the upper wafer W_{U} faces downward.

Thereafter, the holding arm 221 of the inverting mechanism 220 is rotated around the first driver 224 and moved to a location below the upper chuck 230. Then, the upper wafer W_{U} is delivered from the inverting mechanism 220 to the upper chuck 230. The rear surface W_{U2} of the upper wafer W_{U} is attracted and held on the upper chuck 230 (Operation S5 in FIG. 23). At this time, all of the vacuum pumps 241a, 241b and 241c are actuated to purge the upper wafer W_{U} in all regions 230a, 230b and 230c of the upper chuck 230. The upper wafer W_{U} stays in the upper chuck 230 until the lower wafer W_{L} is transferred to the bonding device 41.

While the above-described Operations S1 to S5 are being performed for the upper wafer W_{U}, the lower wafer W_{L} is processed. First, the wafer transfer device 22 takes the lower wafer W_{L} out of the cassette C_{L} and transfers it to the transition device 51 of the processing station 3.

Next, the lower wafer W_{L} is transferred by the wafer transfer device 61 to the surface modifying device 30 and the front surface W_{L1} of the lower wafer W_{L} is modified (Operation S6 in FIG. 23). The modification of the front surface W_{L1} of the lower wafer W_{L} in Operation S6 is the same as that in Operation S1.

Thereafter, the lower wafer W_{L} is transferred by the wafer transfer device 61 to the surface hydrophilizing device 40, and the front surface W_{L1} of the lower wafer W_{L} is cleaned while being hydrophilized (Operation S7 in FIG. 23). The hydrophilization and cleaning of the front surface W_{L1} of the lower wafer W_{L} in Operation S7 is the same as that in Operation S2. Thus, detailed explanation of which will not be repeated. In addition, some of the pure water supplied onto the front surface W_{L1} of the lower wafer W_{L} is used to hydrophilize the front surface W_{L1}, that is, to bond the wafers W_{U} and W_{L}, as will be described later. The remaining excessive pure water remains on the front surface W_{L1} of the lower wafer W_{L}.

Thereafter, the lower wafer W_{L} is transferred by the wafer transfer device 61 to the bonding device 41. The lower wafer W_{L} carried in the bonding device 41 is transferred by the wafer transfer mechanism 201 to the positioning mechanism 210 via the transition 200. Then, the horizontal direction of the lower wafer W_{L} is adjusted by the positioning mechanism 210 (Operation S8 in FIG. 23).

Thereafter, the lower wafer W_{L} is transferred by the wafer transfer mechanism 201 to the lower chuck 231 and is adsorbed to the lower chuck 231 (Operation S9 in FIG. 23). At this time, both of the vacuum pumps 261a and 261b are actuated to purge the lower wafer W_{L} in both regions 231a and 231b of the lower chuck 231. Then, the rear surface W_{L2} of the lower wafer W_{L} is attracted and held on the lower chuck 231 such that the front surface W_{L1} of the lower wafer W_{L} faces upward.

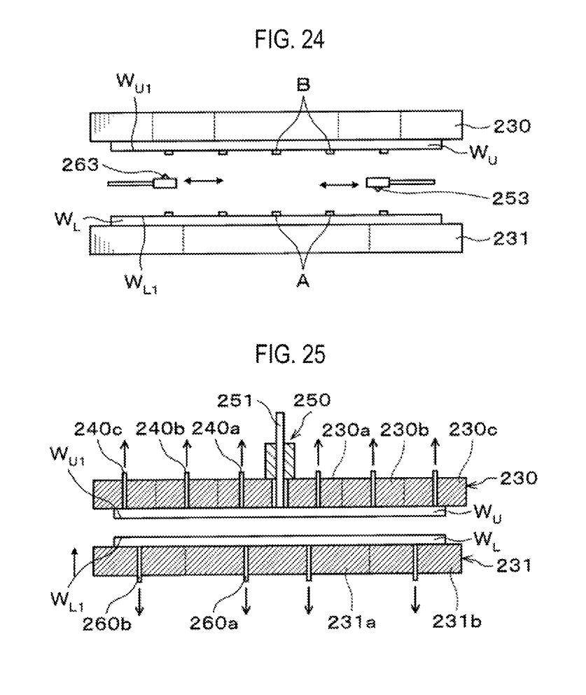

Next, the horizontal direction positioning of the upper wafer W_{U} held on the upper chuck 230 and the lower wafer W_{L} held on the lower chuck 231 is performed. As shown in FIG. 24, a plurality of (for example, four or more) predetermined reference points A is formed in the front surface W_{L1} of the lower wafer W_{L}, and a plurality of (for example, four or more) predetermined reference points B is formed in the front surface W_{U1} of the upper wafer W_{U}. These reference points A and B may be used with, for example, predetermined patterns formed on the wafers W_{U} and W_{L}, respectively. Then, the upper imaging member 253 is moved in the horizontal direction to image the front surface W_{L1} of the lower wafer W_{L}. In addition, the lower imaging member 263 is moved in the horizontal direction to image the front surface W_{U1} of the upper wafer W_{U}. Thereafter, the horizontal position (including the horizontal direction) of the lower wafer W_{L} is adjusted by the lower chuck 231 such that positions of the reference points A of the lower wafer W_{L} indicated on an image picked by the upper imaging member 253 coincide with positions of the reference points B of the upper wafer W_{U} indicated on an image picked by the lower imaging member 263. That is, the lower chuck 231 is horizontally moved by the chuck driver 234 to adjust the horizontal position of the lower wafer W_{L}. Thus, the horizontal positions of the upper wafer W_{U} and the lower wafer W_{L} are adjusted (Operation S10 in FIG. 23). Alternatively, instead of moving the upper imaging member 253 and the lower imaging member 263, the upper chuck 230 and the lower chuck 231 may be moved.

In addition, the horizontal direction of the wafers W_{U} and W_{L} are adjusted thoroughly in Operation S10 although it is adjusted by the positioning mechanism 210 in Operations S3 and S8. Although the predetermined patterns formed on the wafers W_{U} and W_{L} are used as the reference points A and B in Operation S10 in this embodiment, other reference points may be used. For example, the circumference and notch of the wafers W_{U} and W_{L} can be used as the reference points.

Thereafter, the lower chuck 231 is ascended by the chuck driver 234 to place the lower wafer W_{L} at a predetermined position, as shown in FIG. 25. At this time, the lower wafer W_{L} is arranged such that a gap between the front surface W_{L1} of the lower wafer W_{L} and the front surface W_{U1} of the upper wafer W_{U} corresponds to a predetermined distance, for example, 80 μm to 200 μm. Thus, the vertical positions of the upper wafer W_{U} and the lower wafer W_{L} are adjusted (Operation S11 in FIG. 23). In Operations S5 to S11, the upper wafer W_{U} is purged in all regions 230a, 230b and 230c of the upper chuck 230. Similarly, in Operations S9 to S11, the lower wafer W_{L} is purged in both regions 231a and 231b of the lower chuck 231.

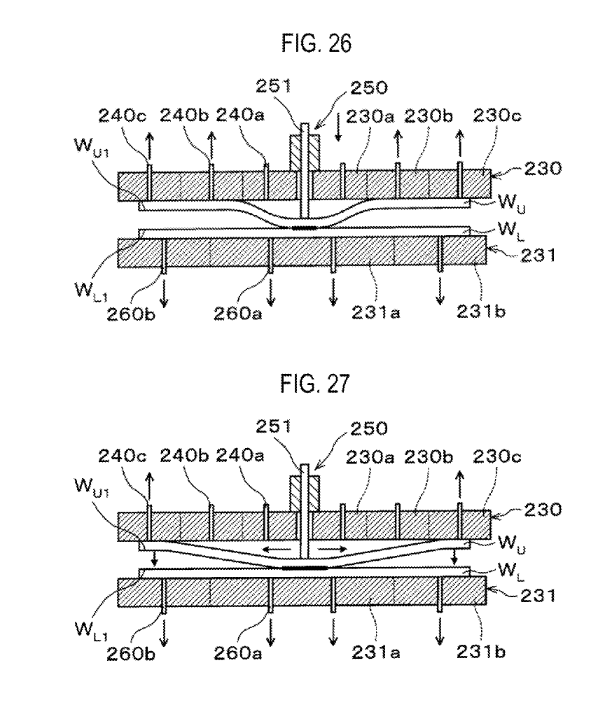

Thereafter, the first vacuum pump 241a is deactivated to stop the purging of the upper wafer W_{U} from the first attracting pipe 240a in the first region 230a, as shown in FIG. 26. At this time, the upper wafer W_{U} remains purged and attracted in the second region 230b and the third region 230c. Thereafter, the pressing pin 251 of the pressing member 250 is descended to descend the upper wafer W_{U} by pressing the central portion of the upper wafer W_{U}. At this time, a load (for example, 200 g) to allow the pressing pin 251 to be moved by 70 μm when the upper wafer W_{U} does not exist is exerted on the pressing pin 251. Then, the pressing member 250 presses the central portion of the upper wafer W_{U} making contact with the central portion of the lower wafer W_{L} (Operation S12 in FIG. 23).

Thus, bonding between the pressed central portions of the upper and lower wafers W_{U} and W_{L} begins (see a thick line portion in FIG. 26). That is, since the front surface W_{U1} of the upper wafer W_{U} and the front surface W_{L1} of the lower wafer W_{L} have been modified in Operations S1 and S6, respectively, a Van der Waals force (inter-molecular force) is first generated between the front surfaces W_{U1} and W_{L1}, and the front surfaces W_{U1} and W_{L1} are then bonded together. In addition, since the front surface W_{U1} of the upper wafer W_{U} and the front surface W_{L1} of the lower wafer W_{L} have been hydrophilized in Operations S2 and S7, respectively, hydrophilic groups between the front surfaces W_{U1} and W_{L1} are hydrogen-bonded (inter-molecular force) to provide a strong bonding between the front surfaces W_{U1} and W_{L1}.

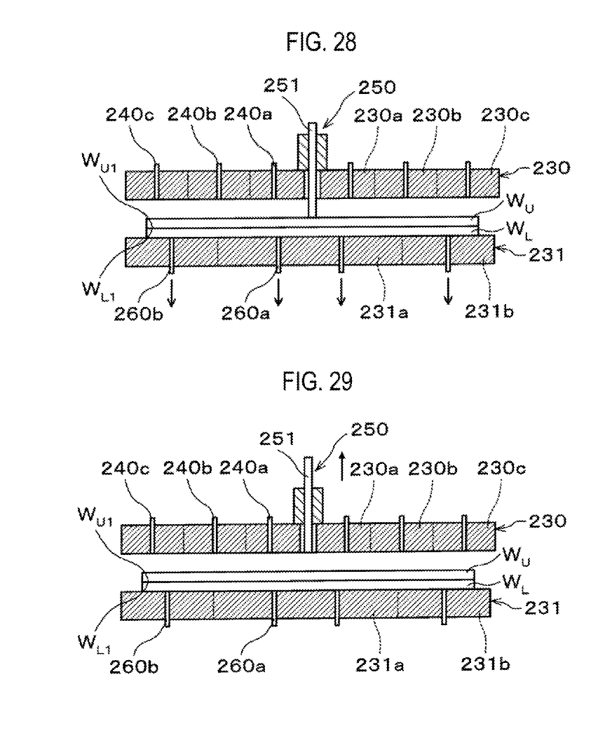

Thereafter, as shown in FIG. 27, under the condition where the central portions of the upper and lower wafers W_{U} and W_{L} are pressed by the pressing member 250, the second vacuum pump 241b is deactivated to stop the purging of the upper wafer W_{U} from the second attracting pipe 240b in the second region 230b. Thus, the upper wafer W_{U} held in the second region 230b falls on the lower wafer W_{L}. Thereafter, the third vacuum pump 241c is deactivated to stop the purging of the upper wafer W_{U} from the third attracting pipe 240c in the third region 230c. In this manner, the purging of the upper wafer W_{U} is stopped in a sequential manner from the central portion to the circumference of the upper wafer W_{U} and the upper wafer W_{U} sequentially falls on and makes contact with the lower wafer W_{L}. Then, this bonding is sequentially expanded by a Van der Waals force and hydrogen bonding between the front surfaces W_{U1} and W_{L1}. Thus, as shown in FIG. 28, the front surface W_{U1} of the upper wafer W_{U} and the front surface W_{L1} of the lower wafer W_{L} make the entire contact with each other to complete the bonding between the upper wafer W_{U} and the lower wafer W_{L} (Operation S13 in FIG. 23).

Thereafter, as shown in FIG. 29, the pressing member 250 is ascended up to the upper chuck 230. In addition, the purging of the lower wafer W_{L} in the lower chuck 231 from the attracting pipes 260a and 260b is stopped to stop the attraction of the lower wafer W_{L} by the lower chuck 231.

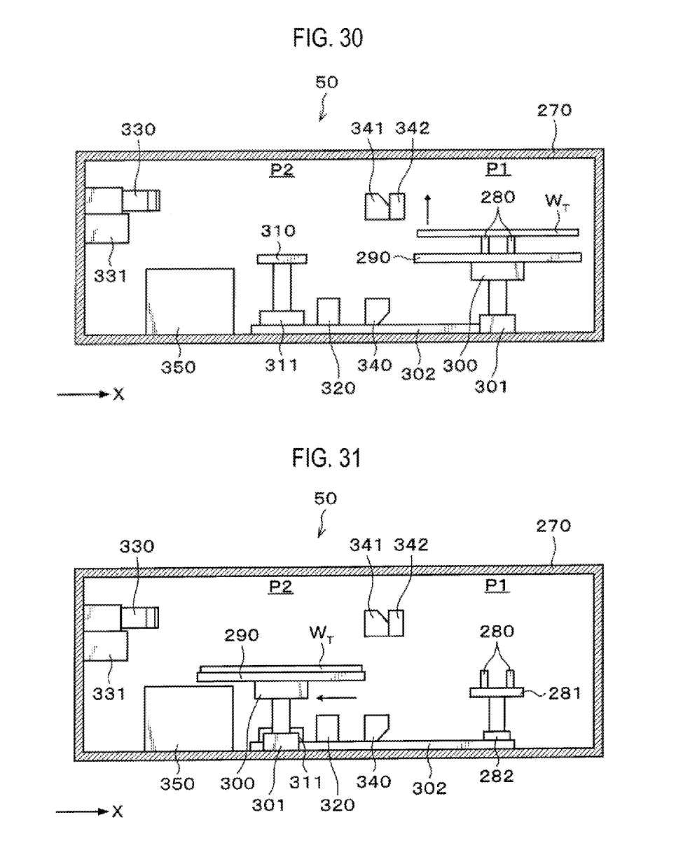

Next, the overlapped wafer W_{T} resulting from the bonding of the upper and lower wafers W_{U} and W_{L} is transferred by the wafer transfer device 61 to the inspection device 50 via the inlet/outlet 271. The overlapped wafer W_{T} transferred to the inspection device 50 is passed from the wafer transfer device 61 to the already elevated elevation pins 280, as shown in FIG. 30. At this time, the first holding unit 290 is waiting at the exchange position P1 below the elevation pins 280. Thereafter, the elevation pins 280 are descended and the overlapped wafer W_{T} is passed from the elevation pins 280 to the first holding unit 290. Afterwards, the first holding unit 290 is moved from the exchange position P1 to the rotation position P2, as shown in FIG. 31.

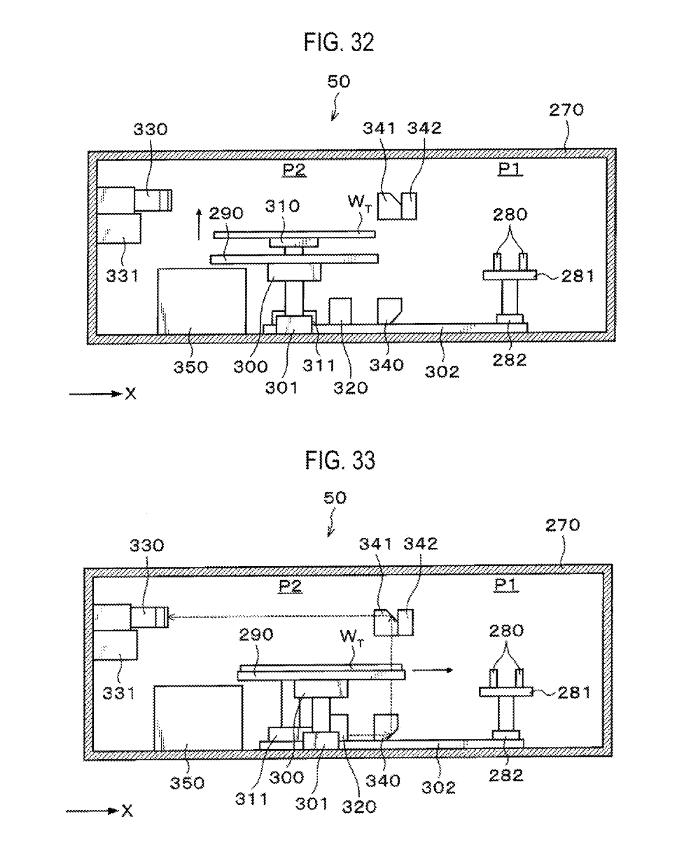

When the first holding unit 290 is moved to the rotation position P2, the second holding unit 310 is ascended, and the overlapped wafer W_{T} is passed from the first holding unit 290 to the second holding unit 310, as shown in FIG. 32. Thereafter, the notch position of the overlapped wafer W_{T} is detected by the position detecting mechanism 350 while the second holding unit 310 is being rotated. Then, the notch position of the overlapped wafer W_{T} is adjusted, and the overlapped wafer W_{T} is arranged at a predetermined position (Operation S14 in FIG. 23).

Once the notch position of the overlapped wafer W_{T} is adjusted, the second holding unit 310 is descended, and the overlapped wafer W_{T} is passed from the second holding unit 310 to the first holding unit 290.

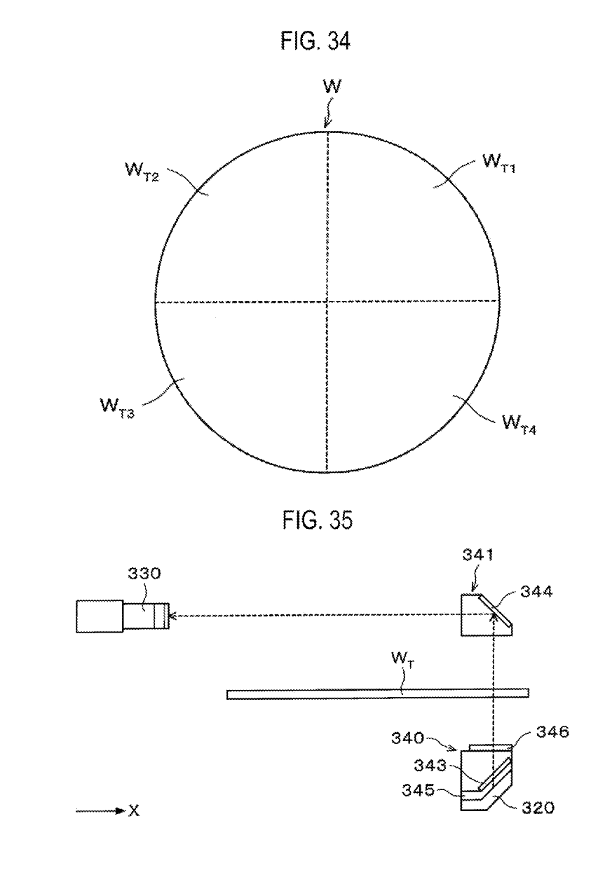

Thereafter, as shown in FIG. 33, under a condition where an infrared ray is emitted from the infrared irradiator 320 to the first direction changer 340, the first holding unit 290 is moved from the rotation position P2 to the exchange position P1. Then, when the overlapped wafer W_{T} held on the first holding unit 290 passes through the first direction changer 340, the infrared ray from the first direction changer 340 transmits through the overlapped wafer W_{T} exposed from the cutout 295. The second direction changer 341 redirects the transmitted infrared ray to the image pickup unit 330. The first holding unit 290 is moved to a position where the infrared irradiation on the overlapped wafer W_{T1} (see FIG. 34) exposed from the cutout 295 is ended, that is, to a side of the second supporting member 292 at the exchange position P1. Then, the overlapped wafer W_{T1} exposed from cutout 295, that is, ¼ of the overlapped wafer W_{T}, is imaged by the image pickup unit 330, as shown in FIG. 34 (Operation S15 in FIG. 23).

This embodiment employs a so-called line sensor type to image the overlapped wafer W_{T} while moving the overlapped wafer W_{T} in Operation S15. An area sensor type to image the entire overlapped wafer W_{T} at a time cannot be used for the internal inspection of the overlapped wafer W_{T} since this type provides a small number of pixels of a picked image.

Once the overlapped wafer W_{T1} is imaged by the image pickup unit 330, the first holding unit 290 continues to be moved to the rotation position P2. Then, similar to that shown in FIG. 32, the second holding unit 310 is ascended, and the overlapped wafer W_{T} is passed from the first holding unit 290 to the second holding unit 310. Thereafter, the second holding unit 310 is rotated by 90 degrees to allow an overlapped wafer W_{T2} shown in FIG. 34 to be exposed from the cutout 295 (Operation S16 in FIG. 23).

Thereafter, the second holding unit 310 is descended, and the overlapped wafer W_{T} is passed from the second holding unit 310 to the first holding unit 290. Then, the above-described Operation S15 is performed, and the overlapped wafer W_{T2} shown in FIG. 34 is imaged by the image pickup unit 330.

Thereafter, these Operations S15 and S16 are repeatedly performed, and the remaining overlapped wafers W_{T3} and W_{T4} shown in FIG. 34 are imaged by the image pickup unit 330. In this manner, images of the overlapped wafers W_{T1} to W_{T4} imaged in division over four times are output from the image pickup unit 330 to the controller 400. The controller 400 combines the images of the overlapped wafer W_{T1} to W_{T4} to obtain the image of the whole overlapped wafer W_{T}. Then, an inspection for internal voids of the overlapped wafer W_{T} is performed based on the image of the whole overlapped wafer W_{T} (Operation S17 in FIG. 23).

When the internal inspection of the overlapped wafer W_{T} is ended, the first holding unit 290 holding the overlapped wafer W_{T} is moved to the exchange position P1. Then, the overlapped wafer W_{T} is passed from the first holding unit 290 to the elevation pins 280. Thereafter, the overlapped wafer W_{T} is passed from the elevation pins 280 to the wafer transfer device 22 and carried out of the inspection device 50 via the inlet/outlet 273.

Thereafter, the overlapped wafer W_{T} is transferred by the wafer transfer device 22 to a cassette C_{T} of a particular cassette loading plate 11. Thus, a series of bonding process for the wafers W_{U} and W_{L} is terminated.

According to the above-described embodiment, since the cutout 295 is formed in the first holding unit 290, ¼ of the overlapped wafer W_{T} held on the first holding unit 290 can be imaged in division in Operation S15. This Operation S15 and the Operation S16 of rotating the overlapped wafer W_{T} by means of the second holding unit 310 are repeatedly performed to image the whole overlapped wafer W_{T} in proper. Accordingly, the interiors of the overlapped wafer W_{T} can be properly inspected based on the image of the whole overlapped wafer W_{T}.

In addition, since the first holding unit 290 has the four supporting members 291 to 294 extending in the direction perpendicular to adjacent supporting members when viewed from the top, the cutout 295 to expose ¼ of the rear surface of the overlapped wafer W_{T} can be properly formed. This allows ¼ of the overlapped wafer W_{T} to be imaged in division in Operation S15. As a result of careful review, the inventors have discovered that it is preferable to image the overlapped wafer W_{T} in the four-division, as in this embodiment, in order for the controller 400 to facilitate combination of images of the overlapped wafer W_{T} imaged in division.

Since the inspection device 50 is provided with a movement mechanism including the driver 301 and the rail 320, the first holding unit 290 can be moved in the horizontal direction and the imaging of the overlapped wafer W_{T} in Operation S15 can be properly performed. Also, since the first holding unit 290 can be moved up to the exchange position P1 and can exchange the overlapped wafer W_{T} with an external device of the inspection device 50 via the elevation pins 280, the configuration of the inspection device 50 can be simplified.

Since the wavelength of the infrared ray emitted from the infrared irradiator 320 is 1100 nm to 2000 nm, the infrared ray can transmit through the overlapped wafer W_{T}. The infrared ray emitted from the infrared irradiator 320 is collected by the cylindrical lens 345 and is evenly distributed throughout the plane of the overlapped wafer by means of the diffusing plate 346. This allows the imaging of the overlapped wafer W_{T} to be properly performed in Operation S15.

Moreover, since the bonding system 1 further includes the surface modifying device 30, the surface hydrophilizing device 40 and the bonding device 41, all of which are used for bonding of the wafers W_{U} and W_{L}, in addition to the inspection device 50; the bonding of the wafers WU and WL and the internal inspection of the overlapped wafer W_{T} can be efficiently performed in a single system, which results in further improvement in a throughput of the wafer bonding process.

Although it has been illustrated in the above embodiment that the infrared irradiator 320 is disposed in the side of the rotation position P2 of the first direction changer 340, it may be integrated with the first direction changer 340 and disposed in the bottom of the first direction changer 340, as shown in FIG. 35. The above-described cylindrical lens 345 is interposed between the infrared irradiator 320 and the first direction changer 340. In addition, a half mirror may be used as the first reflecting mirror 343. Furthermore, the first reflecting mirror may be omitted.

The infrared ray emitted from the infrared irradiator 320 transmits through the overlapped wafer W_{T} via the cylindrical lens 345, the first reflecting mirror 343 and the diffusing plate 346 and is accommodated in the image pickup unit 330 via the second reflecting mirror 344. In this case, like the above embodiment, the overlapped wafer W_{T} can be properly imaged in division in Operation S15, and the interiors of the overlapped wafer W_{T} can be properly inspected based on the image of the whole overlapped wafer W_{T}.

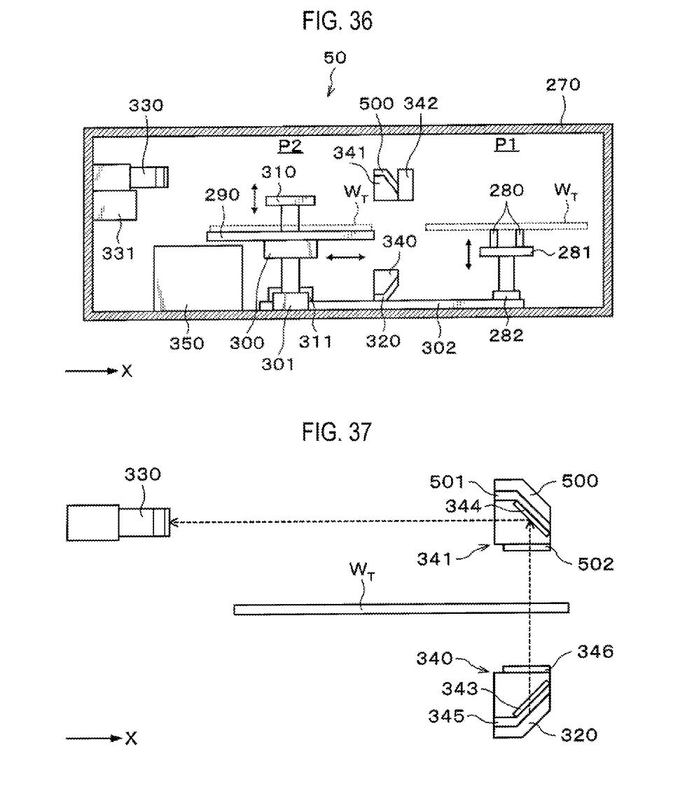

The inspection device 50 of the above embodiment may have another infrared irradiator 500 to irradiate the front surface of the overlapped wafer W_{T} held on the first holding unit 290 with an infrared ray, as shown in FIG. 36. The infrared irradiator 500 is integrated with the second direction changer 341 on the top side thereof, as shown in FIG. 37. A cylindrical lens 501 to collect the infrared ray which is irradiated onto the overlapped wafer W_{T} is interposed between the infrared irradiator 500 and the second direction changer 341. A diffusing plate 502 to make the infrared ray collected by cylindrical lens 501 evenly distributed throughout the plane of the overlapped wafer W_{T} is disposed on the bottom side of the second direction changer 341. In addition, a half mirror may be used as the second reflecting mirror 344.

The second direction changer 341, the second reflecting mirror 344, the infrared irradiator 500, the cylindrical lens 501 and the diffusing plate 502 have the same configuration as the first direction changer 340, the first reflecting mirror 343, the infrared irradiator 320, the cylindrical lens 345 and the diffusing plate 346 in the above embodiment. With the overlapped wafer W_{T} interposed therebetween, the second direction changer 341, the second reflecting mirror 344, the infrared irradiator 500, the cylindrical lens 501 and the diffusing plate 502 are arranged to face the first direction changer 340, the first reflecting mirror 343, the infrared irradiator 320, the cylindrical lens 345 and the diffusing plate 346.

In addition, the support member 331 to support the image pickup unit 330, shown in FIG. 36, has an elevating mechanism (not shown) to elevate the image pickup unit 330.

In this case, when the infrared ray is irradiated from the rear surface of the overlapped wafer W_{T}, the image pickup unit 330 is ascended to a location above the overlapped wafer W_{T}, as shown in FIG. 37. The infrared ray emitted from the infrared irradiator 500 transmits the overlapped wafer W_{T} through the cylindrical lens 345, the first reflecting mirror 343 and the diffusing plate 346 and is received in the image pickup unit 330 via the second reflecting mirror 344. Thus, the overlapped wafer W_{T} is imaged in division.

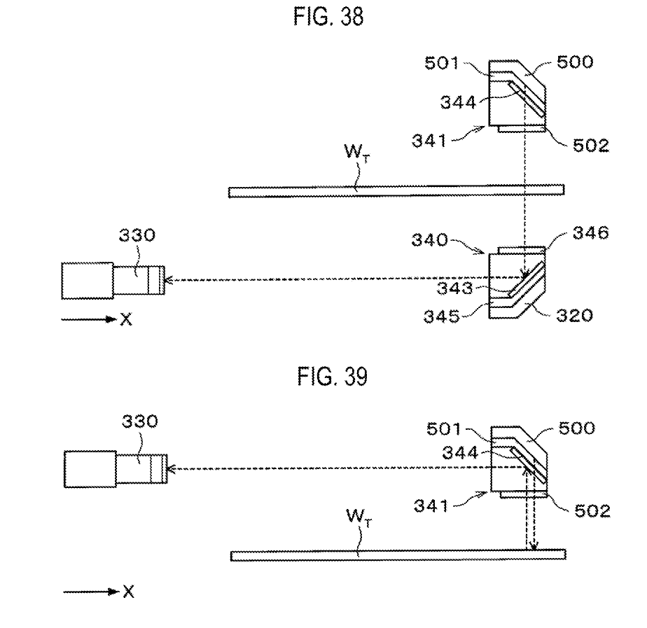

On the other hand, when the infrared ray is irradiated from the front surface of the overlapped wafer W_{T}, the image pickup unit 330 is descended to a location below the overlapped wafer W_{T}, as shown in FIG. 38. The infrared ray emitted from the infrared irradiator 500 transmits through the overlapped wafer W_{T} via the cylindrical lens 501, the second reflecting mirror 344 and the diffusing plate 502 and is received in the image pickup unit 330 via the first reflecting mirror 343. Thus, the overlapped wafer W_{T} is imaged in division.

According to the above embodiment, the infrared irradiation on the rear surface of the overlapped wafer W_{T} by the infrared irradiator 320 or the infrared irradiation on the front surface of the overlapped wafer W_{T} by the infrared irradiator 500 can be optionally performed. Accordingly, the overlapped wafer W_{T} can be properly imaged without depending on the condition of the overlapped wafer W_{T} transferred to the inspection device 50, thereby facilitating a proper internal inspection of the overlapped wafer W_{T}. For example, even if an inspection is to be performed from a particular surface of the overlapped wafer W_{T}, the overlapped wafer W_{T} can be imaged with no need to invert the front and rear surfaces of the overlapped wafer W_{T}.

While it has been illustrated in the above embodiment that the cutout 295 of the first holding unit 290 is formed to expose ¼ of the rear surface of the overlapped wafer W_{T}, the size of the overlapped wafer W_{T} exposed from the first holding unit 290 is not limited thereto. For example, ½, ⅓ or ⅛ of the overlapped wafer W_{T} may be exposed. At any rate, by imaging the overlapped wafer W_{T} in division by means of the image pickup unit 330, any portion of an overlapped wafer held on a holding unit, which could not be otherwise imaged conventionally, can be imaged, thereby facilitating proper imaging of the whole overlapped wafer W_{T}.

While it has been illustrated in the above embodiment that the interiors of the overlapped wafer W_{T} produced by the bonding of the wafers W_{U} and W_{L} by the Van der Waals force and the hydrogen bonding are inspected, the present disclosure can be applied to an overlapped wafer W_{T} produced in different bonding ways.

For example, there may be a case where a large-diameter thin wafer to be processed is used in the recent semiconductor process. In this case, if the wafer to be processed is transferred or polished as it is, the wafer may be likely to be bent or cracked. To avoid this likelihood, for example, in order to reinforce the wafer to be processed, the wafer to be processed is attached to a support wafer via, for example, an adhesive. In addition, the wafer to be processed is a wafer serving as a product and has a plurality of electronic circuits formed in a bonding surface with the support wafer.

The inspection device 50 can be used to perform the internal inspection of an overlapped wafer W_{T} produced by the bonding of the wafer to be processed and the support wafer. However, as described above, electronic circuits are formed on the wafer to be processed and no infrared ray transmits through the electronic circuits. Here, as shown in FIG. 39, the front surface of the overlapped wafer W_{T} is irradiated with an infrared ray from the infrared irradiator 500. This irradiated infrared ray is reflected from a bonding surface of the wafer to be processed and the support wafer in the overlapped wafer W_{T} and is received in the image pickup unit 330 via the second reflecting mirror 344. In this embodiment, the overlapped wafer W_{T} can be also properly imaged to facilitate proper internal inspection of the overlapped wafer W_{T}.

In addition, an overlapped wafer W_{T} may be produced by bonding metal formed on one wafer and metal formed on another wafer. This overlapped wafer W_{T} can be also properly imaged to facilitate proper internal inspection of the overlapped wafer W_{T} by means of the inspection device 50.

Although it has been illustrated in the above embodiment that, in the bonding device 41, the lower chuck 231 is vertically elevated and horizontally moved by means of the chuck driver 234, it may be the upper chuck 230 that is vertically elevated and horizontally moved. In addition, both of the upper chuck 230 and the lower chuck 231 may be vertically elevated and horizontally moved.

In addition, it has been shown in FIG. 39 that the infrared irradiator 500 irradiates the front surface of the overlapped wafer W_{T} with the infrared ray. However, with FIG. 39 inverted, the infrared irradiator 500 may be arranged on the side of the rear surface of the overlapped wafer W_{T} and may irradiate the rear surface of the overlapped wafer W_{T} with the infrared ray.

According to the present disclosure of some embodiments, it is possible to properly inspect the interior of an overlapped substrate produced by bonding one substrate and another substrate.

The present disclosure may also be applied to another types of a substrate such as FPD (Flat Panel Display) and mask reticle for photomask besides wafers.

While certain embodiments have been described, these embodiments have been presented by way of example only, and are not intended to limit the scope of the disclosures. Indeed, the novel methods and apparatuses described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An inspection device for inspecting the interior of an overlapped substrate produced by bonding one substrate and another substrate, comprising:
a first holding unit configured to hold the rear surface of the overlapped substrate and include a cutout formed to expose a portion of the rear surface of the overlapped substrate when viewed from the top;
a second holding unit configured to hold and rotate the overlapped substrate;
an infrared irradiator configured to irradiate the rear surface or front surface exposed from the cutout of the overlapped substrate held on the first holding unit with an infrared ray; and
an image pickup unit configured to receive the infrared ray emitted from the infrared irradiator and image the overlapped substrate held on the first holding unit in division for each of regions exposed from the cutout.

2. The inspection device of claim 1, wherein the cutout is formed to expose ¼ of the rear surface of the overlapped substrate.

3. The inspection device of claim 1, wherein the first holding unit has four supporting members to support the rear surface of the overlapped substrate, and
wherein the four supporting members extend in a direction in which adjacent supporting members are perpendicular when viewed from the top.

4. The inspection device of claim 1, further comprising a movement mechanism configured to move the first holding unit in the horizontal direction.

5. The inspection device of claim 1, further comprising another infrared irradiator configured to irradiate the front surface or rear surface of the overlapped substrate held on the first holding unit with an infrared ray.

6. The inspection device of claim 1, wherein a wavelength of the infrared ray is 1100 nm to 2000 nm.

7. The inspection device of claim 1, further comprising:
a cylindrical lens configured to collect the infrared ray which is irradiated onto the overlapped substrate; and
a diffusing plate configured to make the infrared ray collected by the cylindrical lens uniform in the plane of the overlapped substrate.

8. A bonding system including an inspection device for inspecting the interior of an overlapped substrate produced by bonding one substrate and another substrate, comprising:
a first holding unit configured to hold the rear surface of the overlapped substrate and include a cutout formed to expose a portion of the rear surface of the overlapped substrate when viewed from the top;
a second holding unit configured to hold and rotate the overlapped substrate;
an infrared irradiator configured to irradiate the rear surface or front surface exposed from the cutout of the overlapped substrate held on the first holding unit with an infrared ray; and
an image pickup unit configured to receive the infrared ray emitted from the infrared irradiator and image the overlapped substrate held on the first holding unit in division for each of regions exposed from the cutout, comprising:
a processing station including a plurality of processing apparatuses configured to perform a predetermined process to bond one substrate and another substrate, and a substrate transfer region for transferring the substrates before the bonding or an overlapped substrate after the bonding to the plurality of processing apparatuses; and
a carry-in/carry-out station configured to carry the substrates before the bonding or the overlapped substrate after the bonding in/out of the processing station,
wherein the inspection device is adjacent to the substrate transfer region in the processing station and is arranged in a side of the carry-in/carry-out station.

9. An inspection method for inspecting the interior of an overlapped substrate produced by bonding one substrate and another substrate using an inspection device including:
a first holding unit configured to hold the rear surface of the overlapped substrate and include a cutout formed to expose a portion of the rear surface of the overlapped substrate when viewed from the top;
a second holding unit configured to hold and rotate the overlapped substrate;
an infrared irradiator configured to irradiate the rear surface or front surface exposed from the cutout of the overlapped substrate held on the first holding unit with an infrared ray; and
an image pickup unit configured to receive the infrared ray emitted from the infrared irradiator and image the overlapped substrate held on the first holding unit in division for each of regions exposed from the cutout, the method comprising:
irradiating the rear surface or front surface of the overlapped substrate exposed from the cutout with the infrared ray from the infrared irradiator, under the condition where the overlapped substrate is held on the first holding unit, receiving the irradiated infrared ray in the image pickup unit, and imaging the overlapped substrate exposed from the cutout;
rotating the overlapped substrate by means of the second holding unit, under the condition where the overlapped substrate is held on the second holding unit, such that a portion of the rear surface of the overlapped substrate, which is not imaged by the imaging, is exposed from the cutout; and
repeatedly performing the imaging and the rotating in this order, imaging the whole overlapped substrate, and inspecting the interior of the overlapped substrate.

10. The inspection method of claim 9, wherein the cutout is formed to expose ¼ of the rear surface of the overlapped substrate
wherein the imaging is repeatedly performed four times to image the whole overlapped substrate.

11. The inspection method of claim 9, wherein the inspection device includes a movement mechanism configured to move the first holding unit in the horizontal direction
wherein the imaging and the rotating are performed at different places.

12. The inspection method of claim 9, wherein the inspection device includes another infrared irradiator configured to irradiate the front surface of the overlapped substrate held on the first holding unit with an infrared ray
wherein the infrared irradiation on the rear surface or the front surface of the overlapped substrate exposed from the cutout by the infrared irradiator or the infrared irradiation on the front surface or the rear surface of the overlapped wafer by the another infrared irradiator is optionally performed in the imaging.

13. The inspection method of claim 9, wherein a wavelength of the infrared ray is 1100 nm to 2000 nm.

14. The inspection method of claim 9, wherein, in the imaging, the infrared ray which is irradiated onto the overlapped substrate is collected by a cylindrical lens and is evenly distributed by a diffusing plate in the plane of the overlapped substrate.
